(19) United States
(12) Patent Application Publication
(10) Pub. No.: US 2024/0237452 A1
(43) Pub. Date: Jul. 11, 2024

(54) DISPLAY DEVICE

(71) Applicant: KYOCERA Corporation, Kyoto-shi, Kyoto (JP)

(72) Inventors: Yohei SATO, Muko-shi, Kyoto (JP); Takanobu SUZUKI, Itami-shi, Hyogo (JP); Katsumi AOKI, Yasu-shi, Shiga (JP)

(21) Appl. No.: 18/557,579

(22) PCT Filed: Mar. 29, 2022
(86) PCT No.: PCT/JP2022/015628

§ 371 Date: Oct. 26, 2023

(30) Foreign Application Priority Data
Apr. 27, 2021 (JP) 2021-075119

(51) Int. Cl. H10K 59/131; H10K 59/35

(52) U.S. Cl. CPC H10K 59/1315; H10K 59/353

(57) ABSTRACT

A display device includes an image display unit, drive signal lines, and a drive. The image display unit includes pixel units and emission control signal lines that supply image signals to columns of pixel units of the pixel units. The drive signal lines supply image signals to the emission control signal lines. The drive is configured to supply an image signal to each drive signal line. The image display unit further includes switches each connected to the corresponding drive signal line. One normal drive signal line of the drive signal lines and at least one additional drive signal line are connected to the corresponding emission control signal line through the corresponding switch. Each switch is selectively settable at least to a first conductive state to allow an image signal to be provided from the drive to the corresponding emission control signal line through one normal drive signal line or a second conductive state to allow an image signal to be provided from the drive to the corresponding emission control signal line through at least one additional drive signal line.

### CROSS-REFERENCE TO RELATED APPLICATION

This application claims priority to Japanese Patent Application No. 2021-75119 filed on Apr. 27, 2021, the entire disclosure of which is incorporated herein by reference.

### TECHNICAL FIELD

The present disclosure relates to a display device.

### BACKGROUND OF INVENTION

An example display device includes an image display unit including multiple scanning signal lines and multiple image signal lines located in a grid and including multiple pixel units arranged in a matrix at the intersections of the scanning signal lines and the image signal lines (refer to, for example, Patent Literature 1).

### CITATION LIST

### Patent Literature

Patent Literature 1: Japanese Unexamined Patent Application Publication No. 2006-195119

### SUMMARY

One or more aspects of the present disclosure are directed to a display device.

In one aspect, a display device includes an image display unit, a plurality of drive signal lines, and a drive. The image display unit includes a plurality of pixel units, and a plurality of emission control signal lines that supplies image signals to columns of pixel units of the plurality of pixel units. The plurality of drive signal lines supplies image signals to the plurality of emission control signal lines. The drive is configured to supply an image signal to each of the plurality of drive signal lines. The image display unit further includes a plurality of switches each connected to a corresponding drive signal line of the plurality of drive signal lines. One normal drive signal line of the plurality of drive signal lines and at least one additional drive signal line different from the one normal drive signal line are connected to a corresponding emission control signal line of the plurality of emission control signal lines through a corresponding switch of the plurality of switches. Each of the plurality of switches is selectively settable at least to a first conductive state or a second conductive state. The first conductive state is a state to allow an image signal to be provided from the drive to a corresponding emission control signal line of the plurality of emission control signal lines through the one normal drive signal line of the plurality of drive signal lines. The second conductive state is a state to allow an image signal to be provided from the drive to the corresponding emission control signal line through at least one additional drive signal line.

### BRIEF DESCRIPTION OF THE DRAWINGS

FIG. 1 is a schematic front view of an example tiled display in one or more embodiments.

FIG. 2 is a schematic side view of an example display device according to one or more embodiments.

FIG. 3 is a schematic rear view of the display device according to one or more embodiments.

FIG. 4 is a schematic diagram of an image display unit in portion IV of the display device in FIG. 1, illustrating an example layout of components included in the image display unit.

FIG. 5 is a schematic block diagram of a display device with an example structure according to a first embodiment.

FIG. 6 is a schematic block diagram of a display device as a variation of the display device illustrated in FIG. 5.

FIG. 7 is a circuit diagram of an example switch and an example switch setter in the first embodiment.

FIG. 8 is a timing chart showing example changes in input and output of the switch setter in an uncut state.

FIG. 9 is a timing chart showing example changes in input and output of the switch setter in a cut state.

FIG. 10 is a schematic block diagram of a display device with an example structure according to a second embodiment.

FIG. 11 is a circuit diagram of example switches and switch setters in the second embodiment.

FIG. 12 is a truth table showing the relationship between patterns of signals input into the switch setter from multiple specific signal lines and signals output from the switch setter.

FIG. 13 is a circuit diagram of an example switch in a display device according to a third embodiment.

FIG. 14 is a schematic block diagram of a display device with a first example structure according to a fourth embodiment.

FIG. 15 is a schematic block diagram of a display device with a second example structure according to the fourth embodiment.

FIG. 16 is a schematic block diagram of a display device with a first example structure according to a fifth embodiment.

FIG. 17 is a schematic block diagram of a display device as a variation of the display device illustrated in FIG. 16.

FIG. 18 is a circuit diagram of a switch and a switch setter with first example structures in the fifth embodiment.

FIG. 19 is a schematic block diagram of a display device with a second example structure according to the fifth embodiment.

FIG. 20 is a circuit diagram of switches and switch setters with second example structures in the fifth embodiment.

FIG. 21 is a schematic block diagram of a display device with a first example structure according to a sixth embodiment.

FIG. 22 is a schematic block diagram of a display device with a second example structure according to the sixth embodiment.

FIG. 23 is a schematic block diagram of a display device with a first example structure according to a seventh embodiment.

FIG. 24 is a schematic block diagram of a display device with a second example structure according to the seventh embodiment.

FIG. 25 is a schematic block diagram of a display device with an example structure according to an eighth embodiment.

FIG. 26 is a schematic block diagram of a display device with a first example structure according to a ninth embodiment.

FIG. 27 is a schematic block diagram of a display device with a second example structure according to the ninth embodiment.

### DESCRIPTION OF EMBODIMENTS

An example display device includes an image display unit including multiple scanning signal lines and multiple image signal lines located in a grid and including multiple pixel units arranged in a matrix at the intersections of the scanning signal lines and the image signal lines.

Such a display device may use thinner image signal lines for displaying higher definition images. Any broken image signal line in an image display unit in the display device disable image signals from being provided beyond the broken point, possibly causing poor image display.

The display device may thus include, for example, a circuit outside the image display unit to connect prearranged standby signal lines to the two ends of each image signal line to respond to a broken image signal line in the image display unit.

Multiple display panels may be, for example, tiled together into a single display (also referred to as a tiled display). A display panel can include a portion (also referred to as a frame portion) that does not contribute to display of images between an area (also referred to as an active area) including multiple pixel units and the edges of a substrate in the display panel when, for example, viewed in plan. The frame portion is to be narrower on one side of the substrate in the display panel to form a tiled display including, for example, display panels with less noticeable joints. In other words, a tiled display may include, for example, display panels each with one side of the substrate in the display panel entirely receiving the image display unit (or include frameless display panels). Such a frameless display panel includes, for example, wires (also referred to as signal lines) for providing signals from the back surface to the image display unit on the front surface. The wires include, for example, wires on the back surface (also referred to as back wires) of the display panel and wires on the side surface (also referred to as side wires) of the display panel. Side wires may be formed by, for example, applying a conductive paste to a side surface of, for example, a glass substrate and firing the substrate with the conductive paste.

To form, for example, multiple wires with the pitch of multiple pixel units, multiple notably thin side wires are located on the side surface of the substrate at notably small intervals. For example, the multiple side wires may have a pitch of several tens of micrometers (μm) of multiple pixel units in a display panel having a pitch of several tens of micrometers in response to the resolution of the display panel. Such thinner side wires may break. Any thinner wires other than side wires, such as back wires for providing signals to the image display unit from the back surface, may also break. Any broken wire for, for example, providing image signals to multiple pixel units disables image signals from being provided to one column of pixel units, causing the image displayed on the image display unit to be dark (have a dark line) or have high luminance (have a bright line) at the column, possibly degrading the image quality.

The frameless display panel may also include, for example, as described above, a circuit outside the image display unit to connect prearranged standby signal lines to the two ends of each image signal line. However, this structure cannot respond to a broken wire outside the image display unit, or for example, on the side surface and the back surface of the substrate, although the image signal lines have ends connected to the standby signal lines in the image display unit.

Display devices are thus to respond to broken signal lines outside the image display unit to reduce image quality degradation.

The inventors of the present disclosure have developed a technique for reducing image quality degradation of the display device resulting from any broken signal line outside the image display unit.

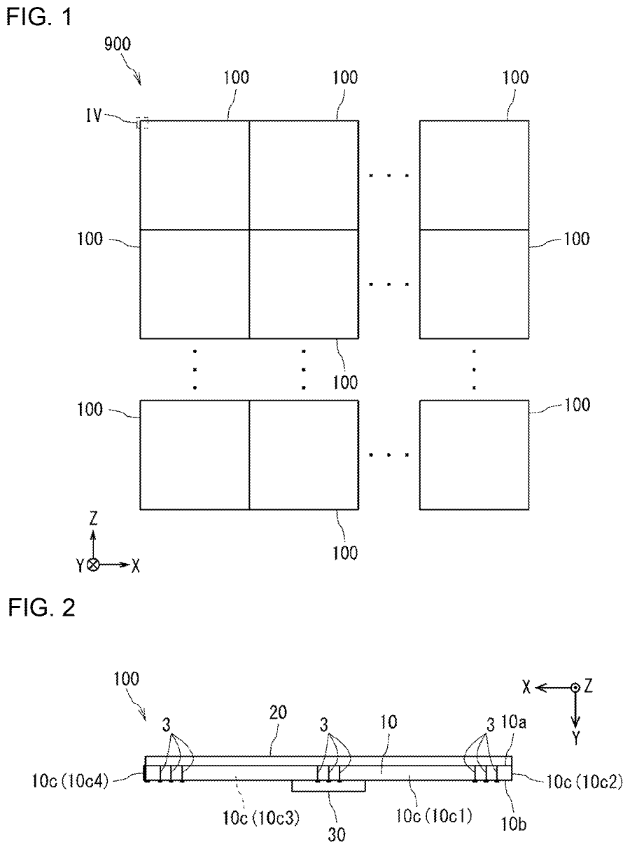

Embodiments of the present disclosure will now be described with reference to the drawings. In the drawings, the same reference numerals denote the components with the same or similar structures and functions, and such components are not described repeatedly. The drawings are schematic. FIGS. 1 to 4 illustrate the right-handed XYZ coordinate system. In the XYZ coordinate system, the positive X-direction is a direction along a first surface 10a of a substrate 10, the positive Z-direction is a direction orthogonal to the positive X-direction along the first surface 10a, and the positive Y-direction is perpendicular to the first surface 10a.

### Example Tiled Display in One or More Embodiments

FIG. 1 is a schematic front view of an example tiled display 900 in one or more embodiments. The tiled display 900 includes, for example, multiple display devices 100 tiled together. In the example in FIG. 1, the tiled display 900 includes the display devices 100 in a matrix along an XZ plane. Each of the display devices 100 is, for example, a flat display panel.

### Example Display Device According to One or More Embodiments

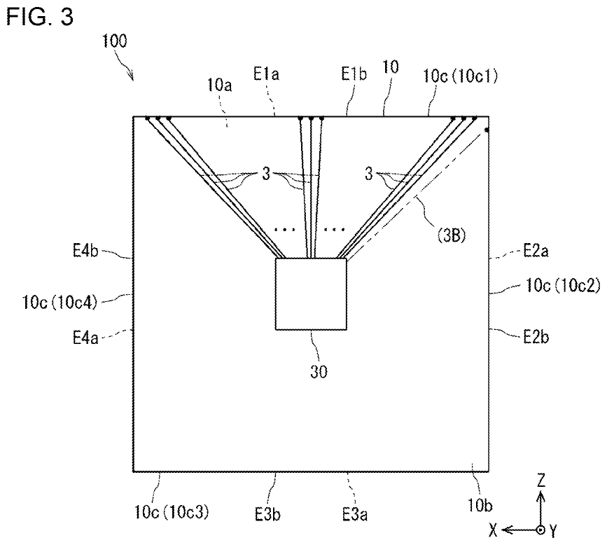

FIG. 2 is a schematic side view of an example display device 100 according to one or more embodiments. FIG. 3 is a schematic rear view of the display device 100 according to one or more embodiments. As illustrated in FIGS. 2 and 3, the display device 100 includes, for example, the substrate 10, an image display unit 20, a drive 30, and multiple drive signal lines 3.

The substrate 10 includes, for example, a first surface (also referred to as a first main surface) 10a, a second surface (also referred to as a second main surface) 10b, and multiple side surfaces 10c. The second surface 10b is opposite to the first surface 10a. Each of the side surfaces 10c connects the first surface 10a and the second surface 10b.

The substrate 10 may be, for example, a flat plate. Each of the first surface 10a and the second surface 10b is, for example, a rectangular surface with four sides. In this case, the side surfaces 10c include a first side surface 10c1, a second side surface 10c2, a third side surface 10c3, and a fourth side surface 10c4. The first side surface 10c1 connects a first side E1a of the first surface 10a and a first side E1b of the second surface 10b. In other words, the first side surface 10c1 includes the first side Ela and the first side E1b as two opposite sides. The second side surface 10c2 connects a second side E2a of the first surface 10a and a second side E2b of the second surface 10b. In other words, the second side surface 10c2 includes the second side E2a and the second side E2b as two opposite sides. The third side surface 10c3 connects a third side E3a of the first surface 10a and a third side E3b of the second surface 10b. In other words, the third side surface 10c3 includes the third side E3a and the third side E3b as two opposite sides. The fourth side surface 10c4 connects a fourth side E4a of the first surface 10a and a fourth side E4b of the second surface 10b. In other words, the fourth side surface 10c4 includes the fourth side E4a and the fourth side E4b as two opposite sides. In the examples in FIGS. 2 and 3, the first surface 10a is a flat surface along an XZ plane and faces in the negative Y-direction. The second surface 10b is a flat surface along an XZ plane and faces in the positive Y-direction. The first surface 10c1 faces in the positive Z-direction. The second surface 10c2 faces in the negative X-direction. The third surface 10c3 faces in the negative Z-direction. The fourth surface 10c4 faces in the positive X-direction.

The substrate 10 is, for example, a glass plate. The glass plate may or may not be transparent. The substrate 10 may be, for example, a colored glass substrate, a frosted glass substrate, a plastic substrate, a ceramic substrate, a metal substrate, or a composite of two or more of these substrates laminated together.

The image display unit 20 displays, for example, images. More specifically, the display device 100 includes, when viewed in plan, the image display unit 20 as a portion in which an image is displayed. The image display unit 20 is, for example, on the first surface 10a of the substrate 10. The image display unit 20 is located to cover, for example, the entire surface of the first surface 10a. The display device 100 includes, for example, the image display unit 20 located on the entire first surface 10a of the substrate 10 (also referred to as a frameless structure) or includes a minimum frame portion.

The drive 30 is located on the second surface 10b of the substrate 10. The drive 30 may include drive elements, such as integrated circuits (ICs) or large-scale integrated circuits (LSIs), mounted on the second surface 10b of the substrate 10 by chip on glass (COG). The drive 30 may be, for example, a circuit board on which drive elements are mounted. The drive 30 may also be, for example, a thin film circuit including a thin film transistor (TFT) including a semiconductor layer of low-temperature polycrystalline silicon (LTPS) formed directly on the second surface 10b of the substrate 10 by a thin film deposition technique such as chemical vapor deposition (CVD).

The drive 30 may also be a drive element on a flexible printed circuit (FPC) connected to connection terminals on the second surface 10b of the substrate 10. In this case, the drive 30 is easily attached to a smaller substrate 10. The drive element can also be replaced easily.

Each of the drive signal lines 3 extends from the second surface 10b of the substrate 10 to the first surface 10a over the side surface 10c. Each of the drive signal lines 3 is located to connect the drive 30 on the second surface 10b of the substrate 10 and the image display unit 20 on the first surface 10a of the substrate 10. In this case, each of the drive signal lines 3 includes, for example, a wire on the second surface 10b of the substrate 10 (also referred to as a back wire) and a wire on the side surface 10c of the substrate 10 (also referred to as a side wire).

### Example Layout of Components of Image Display Unit

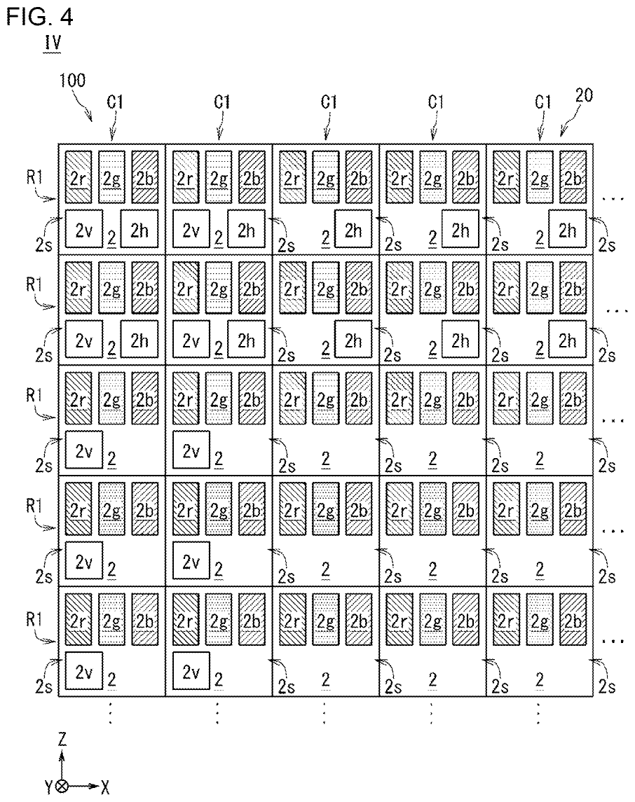

FIG. 4 is a schematic diagram of the image display unit 20 in portion IV of the display device 100 in FIG. 1, illustrating an example layout of components included in the image display unit 20.

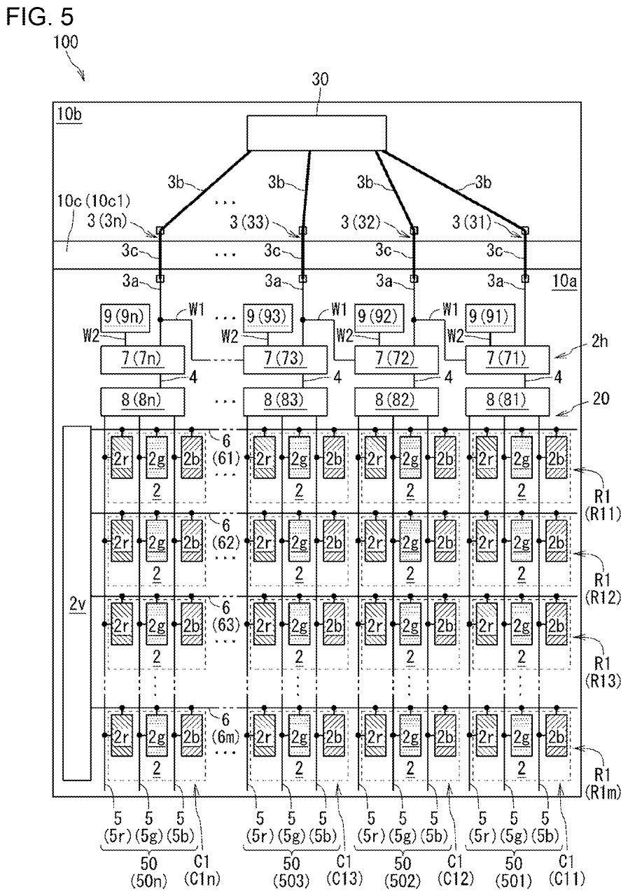

The image display unit 20 includes, for example, multiple pixel units 2. For example, when the display device 100 is viewed in plan from outside the image display unit 20 in a transparent manner, the image display unit 20 includes the pixel units 2 in a matrix. In the example in FIG. 4, multiple rectangular pixel units 2 are arranged densely. More specifically, columns C1 of multiple pixel units 2 (also referred to as pixel columns) each extending in the negative Z-direction (also referred to as an image signal line direction or a first extending direction) as a direction in which emission control signal lines (also referred to as image signal lines) 5 extend (refer to, for example, FIG. 5) are arranged in, for example, the positive X-direction (also referred to as a scanning line direction or a second extending direction) as a direction in which scanning signal lines (also referred to as gate signal lines) 6 extend (refer to, for example, FIG. 5). In other words, rows R1 of multiple pixel units 2 (also referred to as pixel rows) each extending in the positive X-direction as the second extending direction are arranged in the negative Z-direction as the first extension direction.

Each of the pixel units 2 includes, for example, a first subpixel 2r, a second subpixel 2g, and a third subpixel 2b. The first subpixel 2r may emit, for example, light of a first color. The second subpixel 2g may emit, for example, light of a second color different from the first color. The third subpixel 2b may emit, for example, light of a third color different from the first color and the second color. For example, the first color is red, the second color is green, and the third color is blue. Each of the first subpixel 2r, the second subpixel 2g, and the third subpixel 2b includes, for example, a light emitter and an emission controller that controls emission and non-emission of light from the light emitter and the emission intensity of the light emitter.

The light emitters are, for example, micro-light-emitting diodes (LEDs) or organic electroluminescence (EL) elements. The light emitters are located on, for example, an insulating layer on the first surface 10a of the substrate 10. Each light emitter is electrically connected to the emission controller, a positive voltage input line, and a negative voltage input line with feedthrough conductors such as through-holes extending through the insulating layer located in the corresponding pixel unit 2. The positive electrode of the light emitter is connected to the positive voltage input line with, for example, a first through conductor and the emission controller. The negative electrode of the light emitter is connected to the negative voltage input line with, for example, a second through-conductor.

The emission controllers are located between, for example, the first surface 10a and the insulating layer, which is between the light emitters and the first surface 10a, when the display device 100 is viewed in plan from outside the image display unit 20 in a transparent manner. Each emission controller includes, for example, a first transistor, a second transistor, and a capacitive element.

The first transistor functions as, for example, a switch for inputting a drive signal to the light emitter. The first transistor is, for example, a p-channel transistor. The gate electrode of the first transistor is connected to a scanning signal line 6 (refer to, for example, FIG. 5). The source electrode of the first transistor is connected to an emission control signal line 5 (refer to, for example, FIG. 5). The drain electrode of the first transistor is connected to the gate electrode of the second transistor. In response to an on-signal (low or L signal at about −3 to 0 V) as a scanning signal from the scanning signal line 6 input into the gate electrode, the first transistor allows a current to flow through the source electrode and the drain electrode (or shifts to a conductive state). This allows, for example, an emission control signal (L signal: Vg) from the emission control signal line 5 to be input into the gate electrode of the second transistor.

The second transistor drives the light emitter with a current using the potential difference (drive signal) between the positive voltage (anode voltage at about 3 to 5 V) and the negative voltage (cathode voltage at about −3 to 0 V) determined based on the level (voltage) of the emission control signal transmitted from the emission control signal line 5. The second transistor is, for example, a p-channel transistor. In this case, the second transistor includes the source electrode connected to the positive voltage input line, and the drain electrode connected to the negative voltage input line through the light emitter. In response to a L signal as an image signal from the emission control signal line 5 being input into the gate electrode, the second transistor shifts to a conductive state. This allows a drive signal (VDD at about 3 to 5 V) to be input from the positive voltage input line into the light emitter through the second transistor, and causes the light emitter to emit light. The level (voltage) of the image signal (Vg) may be controlled to, for example, control the emission intensity (luminance) of the light emitter.

The capacitive element is located on, for example, the connection line connecting the gate electrode and the source electrode of the second transistor. The capacitive element retains, for example, the voltage of the image signal input into the gate electrode of the second transistor for the period (for one frame) until the next image signal is input (or until the image signal is rewritten with the next image signal).

The emission controller may include, for example, a third transistor between the second transistor and the light emitter to control emission or non-emission of the light emitter. The third transistor is, for example, a p-channel transistor. In this case, the third transistor includes the source electrode connected to the drain electrode of the second transistor, and the drain electrode connected to the positive electrode of the light emitter. In response to a L signal as the emission control signal being input into the gate electrode, the third transistor shifts to a conductive state. This allows the drive signal (VDD) to be input from the positive voltage input line into the light emitter through the second transistor and the third transistor, and causes the light emitter to emit light.

The image display unit 20 includes, for example, an image signal line driver 2h and a scanning signal line driver 2v. The image signal line driver 2h provides, for example, image signals to the emission control signal lines 5. The scanning signal line driver 2v provides, for example, scanning signals to the scanning signal lines 6. The scanning signal line driver 2v is, for example, a shift register.

When, for example, the display device 100 is viewed in plan from outside the image display unit 20 in a transparent manner, each pixel unit 2 includes an area (also referred to as a free area) 2s free of the first subpixel 2r, the second subpixel 2g, and the third subpixel 2b.

The image signal line driver 2h is divided into multiple portions that are located, for example, in free areas 2s in multiple pixel units 2. For example, the image signal line driver 2h is divided into portions that are located in free areas 2s in pixel units 2 included in one or more pixel rows R1 of the image display unit 20. In the example in FIG. 4, the image signal line driver 2h is divided into portions that are located in free areas 2s in pixel units 2 included in two pixel rows R1 of the image display unit 20. More specifically, the image signal line driver 2h is divided into portions that are located in free areas 2s in pixel units 2 included in the two pixel rows R1 located along the edge of the image display unit 20 in the positive Z-direction. The image signal line driver 2h may be divided into portions that are located, for example, in free areas 2s in pixel units 2 included in two or more pixel rows R1 of the image display unit 20.

The scanning signal line driver 2v is divided into portions that are located, for example, in free areas 2s in multiple pixel units 2. For example, the scanning signal line driver 2v is divided into portions that are located in free areas 2s in pixel units 2 included in one or more pixel columns C1 of the image display unit 20. In the example in FIG. 4, the scanning signal line driver 2v is divided into portions that are located in free areas 2s in pixel units 2 included in two pixel columns C1 of the image display unit 20. More specifically, the scanning signal line driver 2v is divided into portions that are located in free area 2s in pixel units 2 included in the two pixel columns C1 located along the edge of the image display unit 20 in the negative X-direction. The scanning signal line driver 2v may be divided into portions that are located, for example, in free areas 2s in pixel units 2 included in two or more pixel columns C1 of the image display unit 20.

### 1. First Embodiment

### 1-1. Structure of Display Device

FIG. 5 is a schematic block diagram of the display device 100 with an example structure according to a first embodiment. As illustrated in FIG. 5, the display device 100 includes, for example, the image display unit 20, the multiple drive signal lines 3, and the drive 30.

### Image Display Unit

The image display unit 20 includes, for example, the multiple pixel units 2 and the multiple emission control signal lines 5.

The pixel units 2 include, for example, m rows×n columns of pixel units 2, where n and m are natural numbers greater than or equal to 4. The pixel units 2 include, for example, multiple pixel rows R1 each including n pixel units 2 and multiple pixel columns C1 each including m pixel units 2. In other words, the pixel units 2 include m pixel rows R1 and n pixel columns C1. More specifically, the m pixel rows R1 include, for example, a first pixel row R11, a second pixel row R12, a third pixel row R13, . . . , and an m-th pixel row R1m. The n pixel columns C1 include, for example, a first pixel column C11, a second pixel column C12, a third pixel column C13, . . . , and an n-th pixel column C1n.

Each of the multiple emission control signal lines 5 can provide, for example, image signals to the columns (pixel columns) C1 of pixel units 2 among the multiple pixel units 2. The emission control signal lines 5 can have image signals provided from, for example, the image signal line driver 2h. The emission control signal lines 5 include, for example, a first emission control signal line 5r, a second emission control signal line 5g, and a third emission control signal line 5b for each pixel column C1. The first emission control signal line 5r may provide, for example, image signals to first subpixels 2r. The second emission control signal line 5g may provide, for example, image signals to second subpixels 2g. The third emission control signal line 5b may provide, for example, image signals to third subpixels 2b. In other words, for n pixel columns C1, n groups 50 of emission control signal lines 5 (also referred to as emission control signal line groups) each include the first emission control signal line 5r, the second emission control signal line 5g, and the third emission control signal line 5b. More specifically, the n emission control signal line groups 50 include, for example, a first emission control signal line group 501, a second emission control signal line group 502, a third emission control signal line group 503, . . . , and an n-th emission control signal line group 50n. In other words, the emission control signal lines 5 include 3×n emission control signal lines 5. Each pixel column C1 includes, for example, m pixel units 2 aligned along one emission control signal line group 50. For example, the first pixel column C11 includes m pixel units 2 aligned along the first emission control signal line group 501. For example, the second pixel column C12 includes m pixel units 2 aligned along the second emission control signal line group 502. For example, the third pixel column C13 includes m pixel units 2 aligned along the third emission control signal line group 503. For example, the n-th pixel column C1n includes m pixel units 2 aligned along the n-th emission control signal line group 50n.

In an emission control signal line group 50, for example, the first emission control signal line 5r may provide image signals to m first subpixels 2r in one pixel column C1. The second emission control signal line 5g may provide image signals to m second subpixels 2g in one pixel column C1. The third emission control signal line 5b may provide image signals to the m third subpixels 2b in one pixel column C1. More specifically, in the first emission control signal line group 501, for example, the first emission control signal line 5r may provide image signals to the m first subpixels 2r in the first pixel column C11. The second emission control signal line 5g may provide image signals to the m second subpixels 2g in the first pixel column C11. The third emission control signal line 5b may provide image signals to the m third subpixels 2b in the first pixel column C11. In the second emission control signal line group 502, for example, the first emission control signal line 5r may provide image signals to the m first subpixels 2r in the second pixel column C12. The second emission control signal line 5g may provide image signals to the m second subpixels 2g in the second pixel column C12. The third emission control signal line 5b may provide image signals to the m third subpixels 2b in the second pixel column C12. In the third emission control signal line group 503, for example, the first emission control signal line 5r can provide image signals to the m first subpixels 2r in the third pixel column C13. The second emission control signal line 5g can provide image signals to the m second subpixels 2g in the third pixel column C13. The third emission control signal line 5b can provide image signals to the m third subpixels 2b in the third pixel column C13. In the n-th emission control signal line group 50n, for example, the first emission control signal line 5r may provide image signals to the m first subpixels 2r in the n-th pixel column C1n. The second emission control signal line 5g may provide image signals to the m second subpixels 2g in the n-th pixel column C1n. The third emission control signal line 5b may provide image signals to the m third subpixels 2b in the n-th pixel column C1n.

The image display unit 20 includes, for example, the multiple scanning signal lines 6. Each of the scanning signal lines 6 can provide, for example, scanning signals to the rows (pixel rows) R1 of the multiple pixel units 2. The scanning signal lines 6 can have scanning signals provided in, for example, a time-sequential (line-sequential) manner from the scanning signal line driver 2v. The scanning signal lines 6 include, for example, m scanning signal lines 6. More specifically, the scanning signal lines 6 include, for example, a first scanning signal line 61, a second scanning signal line 62, a third scanning signal line 63, . . . , and an m-th scanning signal line 6m. Each pixel row R1 includes, for example, n pixel units 2 aligned along a scanning signal line 6. For example, the first pixel row R11 includes n pixel units 2 aligned along the first scanning signal line 61. For example, the second pixel row R12 includes n pixel units 2 aligned along the second scanning signal line 62. For example, the third pixel row R13 includes n pixel units 2 aligned along the third scanning signal line 63. For example, the m-th pixel line R1m includes n pixel units 2 aligned along the m-th scanning signal line 6m. The first scanning signal line 61 can provide, for example, scanning signals to the n pixel unit 2 in the first pixel row R11. The second scanning signal line 62 can provide, for example, scanning signals to the n pixel units 2 in the second pixel row R12. The third scanning signal line 63 can provide, for example, scanning signals to the n pixel unit 2 in the third pixel row R13. The m-th scanning signal line 6m can provide, for example, scanning signals to the n pixel unit 2 in the m-th pixel line R1m. In the first embodiment, for example, each pixel unit 2 can have scanning signals provided to the first subpixel 2r, the second subpixel 2g, and the third subpixel 2b using a single scanning signal line 6.

### Drive Signal Line

The multiple drive signal lines 3 can provide, for example, image signals to the emission control signal lines 5. The drive signal lines 3 include, for example, n drive signal lines 3. More specifically, the drive signal lines 3 include, for example, a first drive signal line 31, a second drive signal line 32, a third drive signal line 33, . . . , and an n-th drive signal line 3n. The first drive signal line 31 can provide, for example, image signals to the first emission control signal line 5r, the second emission control signal line 5g, and the third emission control signal line 5b located along the first pixel column C11. The second drive signal line 32 can provide, for example, image signals to the first emission control signal line 5r, the second emission control signal line 5g, and the third emission control signal line 5b located along the second pixel column C12. The third drive signal line 33 can provide, for example, image signals to the first emission control signal line 5r, the second emission control signal line 5g, and the third emission control signal line 5b located along the third pixel column C13. The n-th drive signal line 3n can provide, for example, image signals to the first emission control signal line 5r, the second emission control signal line 5g, and the third emission control signal line 5b located along the n-th pixel column C1n.

Each of the multiple drive signal lines 3 includes, for example, a first wire portion 3b, a second wire portion 3c, and a third wire portion 3a. The first wire portion 3b (also referred to as a back wire portion) is located on the second surface 10b. The second wire portion 3c (also referred to as a side wire portion) is located on the side surface 10c. The third wire portion 3a (also referred to as a front wire portion) is located on the first surface 10a. The first wire portion 3b is connected to, for example, the drive 30. Each drive signal line 3 includes, for example, the first wire portion 3b, the second wire portion 3c, and the third wire portion 3a connected in series in the stated order. More specifically, the first wire portion 3b is, for example, connected to a conductive first connection portion located on the second surface 10b along the side surface 10c. The second wire portion 3c is, for example, connected to the first connection portion and to a conductive second connection portion located on the first surface 10a along the side surface 10c. The third wire portion 3a is connected to the second connection portion. In this structure, each drive signal line 3 includes, for example, the first wire portion 3b, the first connection portion, the second wire portion 3c, the second connection portion, and the third wire portion 3a that are connected in the stated order. The first connection portion and the second connection portion are for example, conductor pads. The conductor pads are made of a conductive material such as copper (Cu), aluminum (Al), silver (Ag), or gold (Au). The conductor pads may be formed with, for example, a thin film formation method such as plating, vapor deposition, or CVD or with a thick film formation method including applying a conductive paste by printing and then firing the applied paste. The conductive paste contains, for example, particles of a conductor material, uncured resin components, an alcohol solvent, and water.

The second wire portion 3c may be formed by, for example, drying and firing, with heat, the conductive paste applied to the side surface 10c in a predetermined pattern, or curing the conductive paste on the side surface 10c with heat, with light such as ultraviolet (UV) rays, or with a combination of heat and light. The second wire portion 3c may be formed by, for example, a thin film formation method such as plating, vapor deposition, or CVD. A side surface 10c of the substrate 10 may include grooves extending from the first surface 10a to the second surface 10b in portions to receive the second wire portions 3c. In this case, the conductive paste can be easily applied to the grooves as intended areas on the side surface 10c.

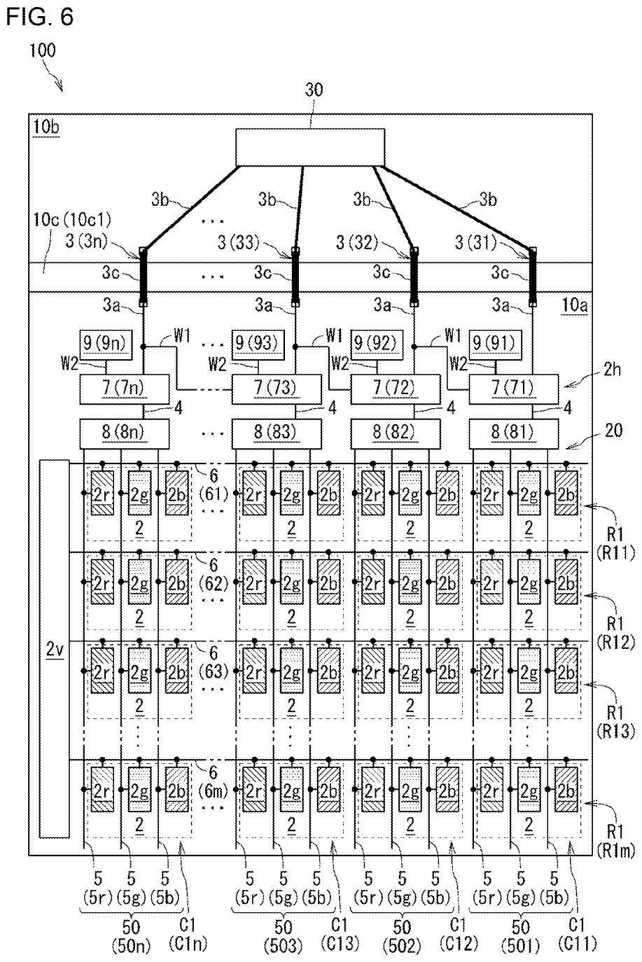

The second wire portions 3c may be wider and/or thicker than either the first wire portions 3b or the third wire portions 3a. For example, as illustrated in FIG. 6, each drive signal line 3 may include the second wire portion 3c (side wire portion) that is wider than each of the first wire portion 3b and the third wire portion 3a. The second wire portion 3c, which is formed by applying and firing the conductive paste, is likely to have a greater resistance than the first wire portion 3b and the third wire portion 3a that are formed by a thin film formation method when the wire portions have the same thickness. The resistance of the second wire portion 3c is thus reduced to easily match with the resistances of the first wire portion 3b and the third wire portion 3a. More specifically, the structure can reduce any increase in connection resistance (contact resistance) between the second wire portion 3c and each of the first wire portion 3b and the third wire portion 3a. This structure also increases the strength of bonding of the second wire portion 3c, which is formed by applying and firing the conductive paste, to the first connection portion (pad) and the second connection portion (pad). The second wire portion 3c may have, but is not limited to, a width about more than once and less than or equal to five times the width of each of the first wire portion 3b and the third wire portion 3a. When the first wire portion 3b, the second wire portion 3c, and the third wire portion 3a have the same width, the second wire portion 3c may be formed to be thicker than each of the first wire portion 3b and the third wire portions 3a to reduce any increase in contact resistance. The second wire portion 3c may have, but is not limited to, a thickness about more than once and less than or equal to ten times the thickness of each of the first wire portion 3b and the third wire portion 3a. This structure also increases the mechanical strength of the second wire portion 3c formed by applying and firing the conductive paste.

The second wire portion 3c may have a width greater than or equal to the width of each of the first connection portion and the second connection portion. This structure increases the strength of bonding between the second wire portion 3c and each of the first connection portion and the second connection portion and decreases the connection resistance between them. The second wire portion 3c may cover each of the first connection portion and the second connection portion. This structure further increases the strength of bonding between the second wire portion 3c and each of the first connection portion and the second connection portion and further decreases the connection resistance between them.

For the same purpose, the second wire portion 3c may be wider and thicker than either the first wire portion 3b or the third wire portion 3a. For the same purpose as well, the second wire portion 3c may be shorter than either the first wire portion 3b or the third wire portion 3a. When the second wire portion 3c has the same width and the same thickness as each of the first wire portion 3b and third wire portion 3a, the above structure functions more effectively.

Each second wire portion 3c may be covered with a protective layer. This structure increases the wear resistance of the second wire portion 3c and the strength of bonding of the second wire portion 3c to the first connection portion and the second connection portion. The material of the protective layer may be a resin such as an acrylic resin or a polycarbonate resin, or an inorganic compound such as silicon oxide (SiO₂) or silicon nitride (Si₃N₄). The protective layer may contain black conductive components such as carbon particles. Such a protective layer increases the conductivity of the second wire portion 3c and allows the narrow frame portion between the edges of the first surface 10a and the image display unit 20 to be less noticeable. The protective layer covering a second wire portion 3c may have no contact with the protective layer covering another second wire portion 3c adjacent to the second wire portion 3c. The protective layers being conductive can reduce short circuiting between the second wire portions 3c adjacent to each other. The protective layers covering the adjacent second wire portions 3c being nonconductive can be placed in contact or continuous with each other.

As illustrated in FIG. 5, the first wire portions 3b, which are connected to the drive 30 at the center of the second surface 10b of the substrate 10, may be longer than the third wire portions 3a. When the first wire portions 3b and the third wire portions 3a are made of the same material, the first wire portions 3b may be wider and/or thicker than the third wire portions 3a. This structure reduces the resistance of the first wire portions 3b and thus reduces the resistance of the drive signal lines 3.

The first wire portions 3b, which are connected to the drive 30 at the center of the second surface 10b of the substrate 10, may be longer than the third wire portions 3a. In this case, the first wire portions 3b may be straight. This structure minimizes the length of the first wire portions 3b and reduces the resistance of the first wire portions 3b.

The first wire portions 3b may have a lower specific resistance (resistivity) than the third wire portions 3a. Under the International Annealed Copper Standard (IACS) measurement (% IACS), which indicates the electric conductivity (reciprocal of resistivity) based on the resistivity 16.78 nanoohm-meter (nΩ2·m) of soft copper being 100, the electric conductivity of various metals and alloys are 105.7% for silver, 100.0% for soft copper, 75.8% for gold, 59.5% for aluminum, 31.8% for tungsten, 31.4% for molybdenum, 28.4% for zinc, 24.2% for nickel, 20.0% for indium, 17.5% for iron, 16.0% for platinum, 15.9% for palladium, 14.6% for tin, 11.0% for niobium, 4.0% for titanium, 71.0 to 83.0% for a chromium-copper alloy, 34.8% for a copper-manganese-nickel alloy, and 26.0 to 43.0% for a copper-zinc alloy. For example, the first wire portions 3b may be made of silver, and the third wire portions 3a may be made of soft copper or aluminum. The first wire portions 3b may be made of soft copper, and the third wire portions 3a may be made of aluminum. The first wire portions 3b may be made of aluminum, and the third wire portion 3a may be made of molybdenum.

The drive 30 provides image signals to, for example, each drive signal line 3. In other words, the drive 30 provides image signals to, for example, each emission control signal line 5 through the drive signal lines 3.

The image display unit 20 includes, for example, multiple switches 7. The switches 7 are included in the image signal line driver 2h. For example, each drive signal line 3 is connected to one switch 7. In other words, each drive signal line 3 is connected to the corresponding switch 7. The multiple switches 7 are, for example, n switches 7. More specifically, the n switches 7 include, for example, a first switch 71, a second switch 72, a third switch 73, . . . , and an n-th switch 7n. The first switch 71 is, for example, connected to the first drive signal line 31, and allows image signals to be provided from the first drive signal line 31 to the first emission control signal line 5r, the second emission control signal line 5g, and the third emission control signal line 5b in the first emission control signal line group 501. The second switch 72 is, for example, connected to the second drive signal line 32, and allows image signals to be provided from the second drive signal line 32 to the first emission control signal line 5r, the second emission control signal line 5g, and the third emission control signal line 5b in the second emission control signal line group 502. The third switch 73 is, for example, connected to the third drive signal line 33, and allows image signals to be provided from the third drive signal line 33 to the first emission control signal line 5r, the second emission control signal line 5g, and the third emission control signal line 5b in the third emission control signal line group 503. The n-th switch 7n is, for example, connected to the n-th drive signal line 3n, and allows image signals to be provided from the n-th drive signal line 3n to the first emission control signal line 5r, the second emission control signal line 5g, and the third emission control signal line 5b in the n-th emission control signal line group 50n.

Each switch 7 is connected at least to, for example, one normal drive signal line 3 among the multiple drive signal lines 3 and to at least one additional drive signal line 3 different from the normal drive signal line 3. In other words, for example, one normal drive signal line 3 and at least one additional drive signal line 3 are at least connected to the corresponding emission control signal lines 5 through the corresponding switch 7. More specifically, one switch 7 may operate to electrically connect at least the normal drive signal line 3 or at least one additional drive signal line 3 to the corresponding emission control signal lines 5. Each switch 7 is settable to a conductive state (also referred to as a first conductive state) to provide image signals from, for example, the drive 30 through one normal drive signal line 3 to the corresponding one of the multiple emission control signal lines 5. Each switch 7 is settable to a conductive state (also referred to as a second conductive state) to provide image signals from, for example, the drive 30 through at least one additional drive signal line different from the normal drive signal line 3 to the corresponding ones of the multiple emission control signal lines 5. Each switch 7 may thus be, for example, selectively settable to either the first conductive state or the second conductive state. Each switch 7 in the image display unit 20 thus allows, for example, image signals to be provided to the emission control signal lines 5 through the additional drive signal line 3 when the normal drive signal line 3 for providing image signals to the emission control signal lines 5 breaks. The display device 100 is thus less likely to be dark (have a dark line) or have high luminance (have a bright line) in one pixel column C1 with no image signals provided to the column. The display device 100 can thus have less image quality degradation resulting from any broken drive signal line 3 outside the image display unit 20.

Each switch 7 is settable selectively at least to either the first conductive state or the second conductive state. In other words, each switch 7 may be settable to one of multiple conductive states, including the first conductive state and the second conductive state. Each switch 7 is settable to one of the first conductive state or the second conductive state. For example, one switch 7 may selectively have a conductive state (e.g., referred to as a third conductive state) to allow multiple image signals to be provided, through multiple normal drive signal lines 3, from the drive 30 to the corresponding emission control signal lines 5. In this case, the multiple image signals can undergo logic operations for input into the corresponding emission control signal lines 5 to produce dithering effect that reduces a large difference in signal strength among the emission control signal lines 5. The logical operation may be performed by a logic circuit located between the drive 30 and the normal drive signal lines 3 to reduce a difference in signal strength between the multiple image signals. One switch 7 may selectively have a conductive state (e.g., referred to as a fourth conductive state) to provide, through an inspection signal line different from the normal drive signal line 3 or the additional drive signal line 3, inspection signals from the drive 30 to the corresponding emission control signal lines 5. This structure allows, before shipment of display devices as products, inspection of each drive display line 3 for its conduction to allow removal of a display device that includes a drive signal line 3 failing to provide intended luminance corresponding to a predetermined image signal or a drive signal line 3 to be a dark line in response to an input predetermined image signal, thus improving manufacturing yield. The structure thus allows, for example, pre-removal of any defective display device that is a part of a composite display (multi-display) including multiple display devices tiled together.

In one example, one normal drive signal line 3 and at least one additional drive signal line 3 may be connected to the corresponding one emission control signal line 5 or multiple emission control signal lines 5 through a switch 7. More specifically, one switch 7 may operate to electrically connect any of one normal drive signal line 3 and at least one additional drive signal line 3 to the corresponding one emission control signal line 5 or multiple emission control signal lines 5.

In the first embodiment, for example, at least one additional drive signal line 3 is at least one of the multiple drive signal lines 3. This structure can reduce, for example, without preparing standby drive signal lines (also referred to as redundant drive signal lines) separately from n normal drive signal lines 3, image quality degradation of the display device 100 resulting from any broken drive signal line 3 outside the image display unit 20. The display device 100 can thus include, for example, a simpler circuit and wire layout. The display device 100 is thus less likely to have, for example, broken redundant drive signal lines. For the display device 100 to display high-definition images, for example, the structure allows multiple pixel units 2 that are otherwise to emit light in response to image signals provided from the drive 30 through normal drive signal line 3, to less noticeably emit light in response to image signals provided from the drive 30 through the additional drive signal line 3.

In this embodiment, at least one additional drive signal line 3 may be, for example, one of the multiple drive signal lines 3. In this case, the display device 100 can include, for example, a simpler circuit and wire layout. In the example in FIG. 5, one normal drive signal line 3 and one additional drive signal line 3 are connected to the corresponding switch 7. More specifically, for example, the first switch 71 is connected to the first drive signal line 31 as one normal drive signal line 3 and to the second drive signal line 32 as one additional drive signal line 3 with a connection wire W1. The second switch 72 is, for example, connected to the second drive signal line 32 as one normal drive signal line 3 and to the third drive signal line 33 as one additional drive signal line 3 with a connection wire W1. The (n−1)th switch 7(n−1) (not illustrated) is, for example, connected to the (n−1) drive signal line 3(n−1) as one normal drive signal line 3 and to the n-th drive signal line 3n as one additional drive signal line 3 with a connection wire W1. The n-th switch 7n may be, for example, connected to the n-th drive signal line 3n as one normal drive signal line 3 and to the (n−1)th drive signal line 3(n−1) (not illustrated) as one additional drive signal line 3 with a connection wire W1. In this example, the additional drive signal line 3 connected to the corresponding switch 7 is the drive signal line 3 adjacent to the normal drive signal line 3 among the multiple drive signal lines 3 connected to the switch 7. In other words, for example, one normal drive signal line 3 and one additional drive signal line 3 connected to the corresponding switch 7 are two normal drive signal lines 3 for two pixel columns C1 adjacent to each other. When, for example, the normal drive signal line 3 breaks, the structure allows multiple pixel units 2 that are otherwise to emit light in response to image signals provided from the drive 30 through the normal drive signal line 3 to emit light at substantially the same luminance as neighboring pixel units 2. The multiple pixel units 2 are thus less noticeable.

The image display unit 20 includes, for example, multiple selectors 8. The selectors 8 are included in the image signal line driver 2h. For example, each switch 7 is connected to one selector 8 with a connection wire 4. In other words, for example, each switch 7 is connected the corresponding selector 8 with the connection wire 4. The multiple selectors 8 are, for example, n selectors 8. More specifically, the n selectors 8 include, for example, a first selector 81, a second selector 82, a third selector 83, . . . , and an n-th selector 8n. The first switch 71 is, for example, connected to the first selector 81. The second switch 72 is, for example, connected to the second selector 82. The third switch 73 is, for example, connected to the third selector 83. The n-th switch 7n is, for example, connected to the n-th selector 8n. Each selector 8 is, for example, connected to the first emission control signal line 5r, the second emission control signal line 5g, and the third emission control signal line 5b. In other words, one selector 8 is located for, for example, each pixel column C1. More specifically, for example, the first selector 81 is connected to the first emission control signal line 5r, the second emission control signal line 5g, and the third emission control signal line 5b extending along the first pixel column C11. The second selector 82 is connected to, for example, the first emission control signal line 5r, the second emission control signal line 5g, and the third emission control signal line 5b extending along the second pixel column C12. The third selector 83 is connected to the first emission control signal line 5r, the second emission control signal line 5g, and the third emission control signal line 5b extending along the third pixel column C13. The n-th selector 8n is connected to the first emission control signal line 5r, the second emission control signal line 5g, and the third emission control signal line 5b extending along the n-th pixel column C1n.

Each selector 8 is settable, in a time-shared manner, to a state to provide, for example, image signals from the corresponding switch 7 to the first emission control signal line 5r, to the second emission control signal line 5g, or to the third emission control signal line 5b. Each selector 8 includes, for example, three transfer gates (also referred to as TGs). In this case, the three TGs include, for example, a first TG, a second TG, and a third TG. The first TG is located on a wire connecting the corresponding switch 7 and first emission control signal line 5r. The second TG is located on a wire connecting the corresponding switch 7 and second emission control signal line 5g. The third TG is located on a wire connecting the corresponding switch 7 and third emission control signal line 5b. The TGs include a p-channel transistor and an n-channel transistor connected in parallel to use the source electrode and the drain electrode in common. The TGs allow a current to flow through the source electrode and the drain electrode (shift to a conductive state) in response to, for example, an input low-potential L signal as a first potential into the gate of the p-channel transistor and an input high-potential H signal as a second potential into the gate of the n-channel transistor. In each selector 8, for example, the first TG, the second TG, and the third TG receive, in a time-shared manner, an input L signal into the gate electrode of the p-channel transistor and an input H signal into the gate electrode of the n-channel transistor. This allows, for example, each selector 8 to be set, in a time-shared manner, to provide image signals from the corresponding switch 7 to the first emission control signal line 5r, to the second emission control signal line 5g, or to the third emission control signal line 5b.

The image display unit 20 includes, for example, multiple switch setters 9. The switch setters 9 are included in the image signal line driver 2h. Each switch 7 is connected to one switch setter 9. In other words, each switch 7 is connected the corresponding switch setter 9. For example, each switch 7 is connected to one switch setter 9 with a connection wire W2. In other words, for example, each switch 7 is connected to the corresponding switch setter 9 with the connection wire W2. The multiple switch setters 9 are, for example, n switch setters 9. More specifically, the n switch setters 9 include, for example, a first switch setter 91, a second switch setter 92, a third switch setter 93, . . . , and an n-th switch setter 9n. The first switch 71 is, for example, connected to the first switch setter 91. The second switch 72 is, for example, connected to the second switch setter 92. The third switch 73 is, for example, connected to the third switch setter 93. The n-th switch 7n is, for example, connected to the n-th switch setter 9n.

Each switch setter 9 can selectively provide, for example, either a first signal or a second signal to one of the switches 7 connected to the switch setter 9. More specifically, for example, the first switch setter 91 can selectively provide either the first signal or the second signal to the first switch 71. The second switch setter 92 can selectively provide, for example, either the first signal or the second signal to the second switch 72. The third switch setter 93 can selectively provide, for example, either the first signal or the second signal to the third switch 73. The n-th switch setter 9n can selectively provide, for example, either the first signal or the second signal to the n-th switch 7n. Each switch 7 is set to the first conductive state in response to the first signal from one of the switch setters 9 connected to the switch 7 and to the second conductive state in response to the second signal from one of the switch setters 9 connected to the switch 7. More specifically, for example, the first switch 71 is set to the first conductive state in response to the first signal from the first switch setter 91 and to the second conductive state in response to the second signal from the first switch setter 91. The second switch 72 is set to, for example, the first conductive state in response to the first signal from the second switch setter 92 and to the second conductive state in response to the second signal from the second switch setter 92. The third switch 73 is set to, for example, the first conductive state in response to the first signal from the third switch setter 93 and to the second conductive state in response to the second signal from the third switch setter 93. The n-th switch 7n is set to, for example, the first conductive state in response to the first signal from the n-th switch setter 9n and to the second conductive state in response to the second signal from the n-th switch setter 9n. In the first embodiment, for example, the first signal is a low-potential L signal, and the second signal is a high-potential H signal.

### 1-2. Examples of Switches and Switch Setters

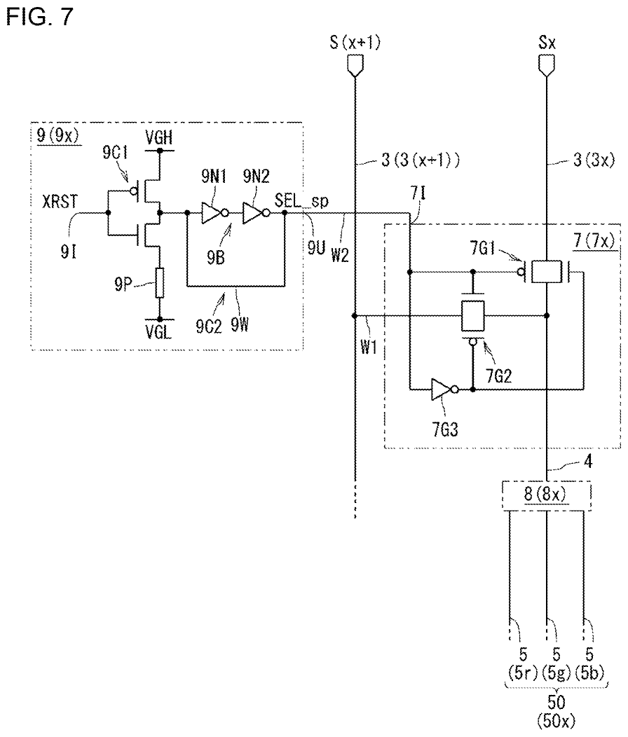

FIG. 7 is a circuit diagram of an example switch 7 and an example switch setter 9. FIG. 7 illustrates an example x-th switch 7x (x is a natural number from 1 to n−1) and an example x-th switch setter 9x.

### Switch

As illustrated in FIG. 7, each switch 7 includes, for example, a first gate 7G1, a second gate 7G2, a third gate 7G3, and a signal input section 7I.

The first gate 7G1 is located on, for example, a wire connecting an x-th drive signal line 3x and an x-th selector 8x. The first gate 7G1 is settable to a conductive state that allows, for example, an image signal Sx to be provided from the x-th drive signal line 3x to the emission control signal lines 5 in an x-th emission control signal line group 50x in response to one or more particular signals being input. The first gate 7G1 is, for example, a TG. In this case, the first gate 7G1 includes an input first electrode connected to the x-th drive signal line 3x and an output second electrode connected to the emission control signal lines 5 through the x-th selector 8x. The TG includes a p-channel transistor and an n-channel transistor connected in parallel to use the source electrode and the drain electrode in common. The first gate 7G1 allows a current to flow through the first electrode and the second electrode (or shifts to a conductive state) in response to, for example, an input low-potential signal (L signal) into the gate electrode of the p-channel transistor and to an input high-potential signal (H signal) into the gate electrode of the n-channel transistor. In this state, for example, the image signal Sx can be provided from the x-th drive signal line 3x to the emission control signal lines 5 in the x-th emission control signal line group 50x through the first gate 7G1.

The second gate 7G2 is located on, for example, a wire connecting an (x+1)th drive signal line 3(x+1) and the x-th selector 8x. The first gate 7G1 is settable to a conductive state that allows, for example, an image signal S(x+1) to be provided from the (x+1)th drive signal line 3(x+1) to the emission control signal lines 5 in the x-th emission control signal line group 50x in response to one or more particular signals being input. The second gate 7G2 is, for example, a TG. In this case, the second gate 7G2 includes an input third electrode connected to the (x+1)th drive signal line 3(x+1) and an output fourth electrode connected to the emission control signal lines 5 through the x-th selector 8x. The second gate 7G2 allows a current to flow through the third electrode and the fourth electrode (or shifts to a conductive state) in response to an input low-potential signal (L signal) into the gate electrode of the p-channel transistor and to an input high-potential signal (H signal) into the gate electrode of the n-channel transistor. In this state, for example, the image signal S(x+1) can be provided from the (x+1)th drive signal line 3(x+1) to the emission control signal lines 5 in the x-th emission control signal line group 50x through the second gate 7G2.

The signal input section 7I receives, for example, input signals from outside the switch 7. In the first embodiment, signals are input into the signal input section 7I from the corresponding switch setter 9. The signal input section 7I is connected to, for example, the gate electrode of the p-channel transistor of the first gate 7G1 and the gate electrode of the n-channel transistor of the second gate 7G2. The signal input section 7I is also connected to the gate electrode of the n-channel transistor of the first gate 7G1 and the gate electrode of the p-channel transistor of the second gate 7G2 through, for example, the third gate 7G3. The input signals into the signal input section 7I are thus provided to, for example, the gate electrode of the p-channel transistor of the first gate 7G1, the gate electrode of the n-channel transistor of the second gate 7G2, and the input end of the third gate 7G3.

The third gate 7G3 is located on, for example, a wire connecting the signal input section 7I, the gate electrode of the n-channel transistor of the first gate 7G1, and the gate electrode of the p-channel transistor of the second gate 7G2. In other words, the third gate 7G3 is located between the signal input section 7I and the gate electrode of the n-channel transistor of the first gate 7G1 and between the signal input section 7I and the gate electrode of the p-channel transistor of the second gate 7G2. The third gate 7G3 thus includes, for example, the input end connected to the signal input section 7I and the output end connected to the gate electrode of the n-channel transistor of the first gate 7G1 and the gate electrode of the p-channel transistor of the second gate 7G2. The third gate 7G3 is, for example, a NOT gate that inverts the logic level of the voltage of a signal input into the input end and outputs the inverted signal from the output end. For example, in response to an input L signal into the signal input section 7I, the third gate 7G3 inverts the L signal to a H signal, which is provided to the gate electrode of the n-channel transistor of the first gate 7G1 and the gate electrode of the p-channel transistor of the second gate 7G2. For example, in response to an input H signal into the signal input section 7I, the third gate 7G3 inverts the H signal to a L signal, which is provided to the gate electrode of the n-channel transistor of the first gate 7G1 and the gate electrode of the p-channel transistor of the second gate 7G2.

In the example below, a L signal is input into the signal input section 7I in the x-th switch 7x with the above structure. In this example, the first gate 7G1 receives an input L signal into the gate electrode of the p-channel transistor and an input H signal into the gate electrode of the n-channel transistor. The first gate 7G1 thus allows, for example, a current to flow through the first electrode and the second electrode (or shifts to a conductive state). The second gate 7G2 receives, for example, an input H signal into the gate electrode of the p-channel transistor and an input L signal into the gate electrode of the n-channel transistor. The second gate 7G2 thus blocks, for example, the current flowing through the third electrode and the fourth electrode (or shifts to a non-conductive state). This sets, for example, the x-th switch 7x to a state (first conductive state) to allow the image signal Sx to be provided from the x-th drive signal line 3x to the emission control signal lines 5 in the x-th emission control signal line group 50x through the first gate 7G1.

In the example below, a H signal is input into the signal input section 7I in the x-th switch 7x with the above structure. In this example, the first gate 7G1 receives an input H signal into the gate electrode of the p-channel transistor and an input L signal into the gate electrode of the n-channel transistor. The first gate 7G1 thus blocks, for example, the current flowing through the first electrode and the second electrode (or shifts to a non-conductive state). The second gate 7G2 receives, for example, an input L signal into the gate electrode of the p-channel transistor and an input H signal into the gate electrode of the n-channel transistor. The second gate 7G2 thus allows, for example, a current to flow through the third electrode and the fourth electrode (or shifts to a conductive state). This sets, for example, the x-th switch 7x to a state (second conductive state) to allow the image signal S(x+1) to be provided from the (x+1)th drive signal line 3(x+1) to the emission control signal lines 5 in the x-th emission control signal line group 50x through the second gate 7G2.

The x-th switch 7x is thus set to, for example, the first conductive state in response to a L signal as the first signal from the x-th switch setter 9x and to the second conductive state in response to a H signal as the second signal from the x-th switch setter 9x. In other words, each switch 7 is set to, for example, the first conductive state in response to a L signal as the first signal from one of the multiple switch setters 9 connected to the switch 7 and to the second conductive state in response to a H signal as the second signal from one of the multiple switch setters 9 connected to the switch 7.

### Switch Setter

As illustrated in FIG. 7, each switch setter 9 includes, for example, a first circuit 9C1, a second circuit 9C2, a signal input section 9I, and a signal output section 9U.

The signal input section 9I receives input signals from outside the switch setter 9. Signals are input into the signal input section 9I from, for example, the drive 30 through a predetermined wire.

The first circuit 9C1 is, for example, a complementary metal-oxide semiconductor (CMOS) NOT circuit as an inverter logic circuit. The CMOS NOT circuit includes, for example, a p-channel transistor and an n-channel transistor connected in series between a positive power line for applying a positive potential VGH and a negative power line for applying a negative potential VGL. The negative potential VGL may be, for example, a reference potential (GND) or 0 volts. More specifically, the p-channel transistor includes the source electrode connected to the positive power line and the drain electrode connected to the drain electrode of the n-channel transistor. The n-channel transistor includes the source electrode connected to the negative power line. The CMOS NOT circuit incudes an input section (also referred to as a first input section) that is a portion in which the gate electrode of the p-channel transistor is connected to the gate electrode of the n-channel transistor, and an output section (also referred to as a first output section) that is a portion in which the drain electrode of the p-channel transistor is connected to the drain electrode of the n-channel transistor. The CMOS NOT circuit can invert the logic level of the voltage of an input signal into the first input section and output the resultant signal from the first output section. The first input section of the CMOS NOT circuit is connected to the signal input section 9I. The first circuit 9C1 can thus output a H signal from the first output section in response to an input L signal into the first input section from the signal input section 9I and output a L signal from the first output section in response to an input H signal into the first input section from the signal input section 9I. The first circuit 9C1 includes, for example, a specific wire portion 9P on a wire connecting the source electrode of the n-channel transistor and the negative power line. In this case, for example, each switch setter 9 includes the specific wire portion 9P. The specific wire portion 9P is a portion to be cut as described later. The specific wire portion 9P located on an insulating layer on the first surface 10a of the substrate 10 can be easily cut by, for example, melting by laser beam irradiation, mechanical cutting using, for example, a grinding device, or chemical cutting using, for example, etching. In other words, the specific wire portion 9P is a permanent conductive-nonconductive selector that can be permanently either in a conductive state or in a nonconductive state.

The second circuit 9C2 includes, for example, a buffer circuit 9B including two NOT gates 9N1 and 9N2 in a cascade connection. The second circuit 9C2 also includes a wire portion 9W connected in parallel with the buffer circuit 9B. The second circuit 9C2 includes, for example, an input section (also referred to as a second input section) connected to the first output section of the first circuit 9C1 and an output section (second output section) connected to the signal output section 9U. The buffer circuit 9B can output a signal input into the second input section from the first output section of the first circuit 9C1 after stabilizing and correcting the voltage level of the signal. For example, the second circuit 9C2 can output a corrected L signal from the second output section in response to an input L signal into the second input section from the first circuit 9C1, and a stabilized and corrected H signal from the second output section in response to an input H signal into the second input section from the first circuit 9C1.

In the example below, a L signal is input into the signal input section 9I in the x-th switch setter 9x with the above structure. In this example, the first circuit 9C1 inverts the L signal and outputs a H signal. The second circuit 9C2 outputs a stabilized and corrected H signal. The signal output section 9U thus outputs the H signal to the signal input section 7I in the x-th switch 7x.

In the example below, a H signal is input into the signal input section 9I in the x-th switch setter 9x with the above structure. In this example, the first circuit 9C1 inverts the H signal and outputs a L signal. The second circuit 9C2 outputs a stabilized and corrected L signal. The signal output section 9U thus outputs the L signal to the signal input section 7I in the x-th switch 7x.

### Example Switching of Transmission Path of Image Signal

Each switch setter 9 switches the relationship between the signal input into the signal input section 9I and the signal output from the signal output section 9U based on whether the specific wire portion 9P is cut.

When, for example, the specific wire portion 9P is yet to be cut (also referred to as being in an uncut state), the switch setter 9 outputs a H signal from the signal output section 9U in response to an input L signal into the signal input section 9I, and outputs a L signal from the signal output section 9U in response to an input H signal into the signal input section 9I. When, for example, the specific wire portion 9P has been cut (also referred to as being in a cut state), the switch setter 9 outputs a H signal from the signal output section 9U in response to an input L signal into the signal input section 9I, and continues outputting a H signal in response to a H signal subsequently input into the signal input section 9I. The switch setter 9 in the cut state thus continues, for example, outputting a H signal from the signal output section 9U in response to an input H signal into the signal input section 9I, once receiving an input L signal into the signal input section 9I and outputting a H signal from the signal output section 9U. In this state, the switch setter 9 stores, for example, the state in which the second circuit 9C2 continues outputting a H signal from the signal output section 9U.

The structure according to the first embodiment uses, for example, the relationship between the input and the output of each switch setter 9 that changes based on the cut or uncut state of the specific wire portion 9P to set the corresponding switch 7 to the first conductive state or the second conductive state.

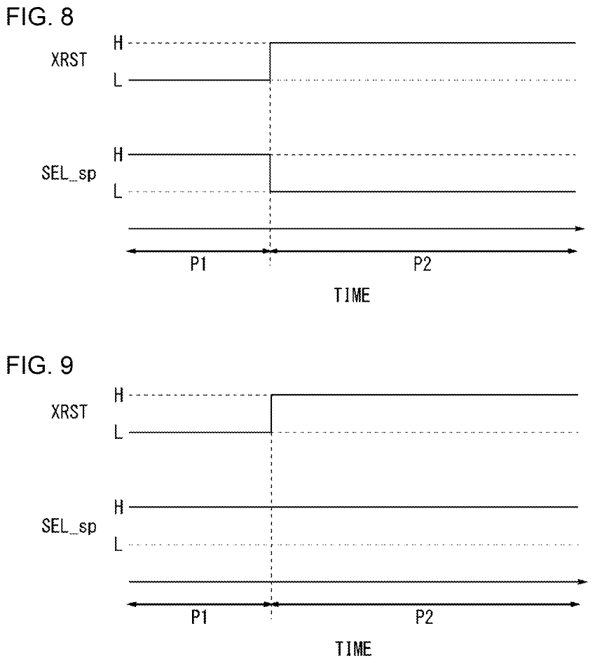

FIG. 8 is a timing chart illustrating example changes in the input and output of the switch setter 9 in the uncut state. In a first period P1, as illustrated in the example in FIG. 8, the switch setter 9 in the uncut state receives, as a L signal, an input signal XRST into the signal input section 9I and outputs, as a H signal, a signal SEL_sp from the signal output section 9U. In a second period P2 subsequent to the first period P1, the switch setter 9 in the uncut state receives, as a H signal, the input signal XRST into the signal input section 9I and outputs, as a L signal, the signal SEL_sp from the signal output section 9U. In this state, for example, a L signal as the first signal is input into the x-th switch 7x from the x-th switch setter 9x in the uncut state. This sets, for example, the x-th switch 7x to a state (first conductive state) to allow the image signal Sx to be provided from the x-th drive signal line 3x as the normal drive signal line 3 to the emission control signal lines 5 in the x-th emission control signal line group 50x.

FIG. 9 is a timing chart illustrating example changes in the input and output of the switch setter 9 in the cut state. In the first period P1, as illustrated in the example in FIG. 9, the switch setter 9 in the cut state receives, as a L signal, the input signal XRST into the signal input section 9I and outputs, as a H signal, the signal SEL_sp from the signal output section 9U. In the subsequent second period P2, the switch setter 9 in the cut state continues outputting the signal SEL_sp as a H signal from the signal output section 9U although the signal XRST as a H signal is input into the signal input section 9I. In this state, for example, a H signal as the second signal is input into the x-th switch 7x from the x-th switch setter 9x in the cut state. This sets, for example, the x-th switch 7x to a state (second conductive state) to allow an image signal S(x+1) to be provided from the (x+1)th drive signal line 3(x+1) as an additional drive signal line 3 to the emission control signal lines 5 in the x-th emission control signal line group 50x.

In the second period P2, for example, the x-th switch setter 9x can set the signal provided to the x-th switch 7x from a first potential L signal to a second potential H signal in the manner described above when the specific wire portion 9P is cut. In other words, each switch setter 9 can provide a H signal as the second signal to one of the switches 7 connected to the switch setter 9 when the specific wire portion 9P is cut. More specifically, for example, the first switch setter 91 can provide a H signal as the second signal to the first switch 71 when the specific wire portion 9P is cut. The second switch setter 92 can provide, for example, a H signal as the second signal to the second switch 72 when the specific wire portion 9P is cut. The third switch setter 93 can provide, for example, a H signal as the second signal to the third switch 73 when the specific wire portion 9P is cut. The n-th switch setter 9n can provide, for example, a H signal as the second signal to the n-th switch 7n when the specific wire portion 9P is cut. The x-th switch 7x is thus settable to, for example, the second conductive state in response to a H signal as the second signal from the x-th switch setter 9x. In other words, each switch 7 is settable to the second conductive state in response to a H signal as the second signal from one of the switch setters 9 connected to the switch 7. More specifically, for example, the first switch 71 is settable to the second conductive state in response to a H signal as the second signal from the first switch setter 91. The second switch 72 is settable to, for example, the second conductive state in response to a H signal as the second signal from the second switch setter 92. The third switch 73 is settable to, for example, the second conductive state in response to a H signal as the second signal from the third switch setter 93. The n-th switch 7n is settable to, for example, the second conductive state in response to a H signal as the second signal from the n-th switch setter 9n. The above structure allows, for example, the switch setters 9 to have smaller circuits for changing the states of conduction in the switches 7.

Each switch 7 is set to the second conductive state when, for example, a pixel column C1 with a dark line or a bright line is identified in the inspection of the display device 100 before shipment. In such a process, for example, the specific wire portion 9P of the switch setter 9 corresponding to the defective pixel column C1 is cut to set the switch 7 corresponding to the pixel column C1 to the second conductive state. The switch 7 may be set to the second conductive state when, for example, a pixel column C1 with a dark line or a bright line is identified in repair or other maintenance of the display device 100.

### 1-3. Overview of First Embodiment

As described above, the display device 100 includes, for example, the multiple switches 7 each connected to the corresponding one of the multiple drive signal lines 3. Each switch 7 is connected to the corresponding one of the normal drive signal lines 3 and at least one additional drive signal line 3. Each switch 7 can be selectively set to, for example, one of the first conductive state in which the switch 7 allows image signals to be provided from the drive 30 to the corresponding emission control signal lines 5 through one normal drive signal line 3 and the second conductive state in which the switch 7 allows image signals to be provided from the drive 30 to the corresponding emission control signal lines 5 through at least one additional drive signal line 3. The switch 7 in the image display unit 20 thus allows, when, for example, the normal drive signal line 3 for providing image signals to the emission control signal lines 5 breaks, image signals to be provided to the emission control signal lines 5 through the additional drive signal line 3 different from the normal drive signal line 3. The display device 100 is thus less likely to be dark (have a dark line) or have high luminance (have a bright line) in one pixel column C1 with no image signals provided to the column. The display device 100 can thus have less image quality degradation resulting from any broken drive signal line 3 outside the image display unit 20.

### 2. Other Embodiments

The present disclosure is not limited to the first embodiment and may be changed or varied in various manners without departing from the spirit and scope of the present disclosure.

### 2-1. Second Embodiment

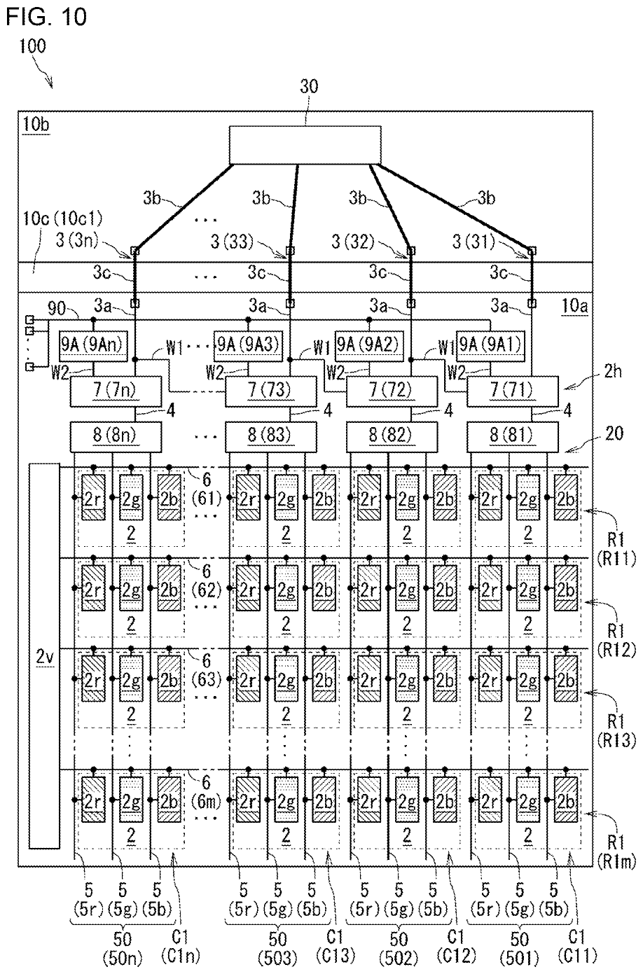

In the first embodiment, for example, the switch setters 9 may be replaced with switch setters 9A as illustrated in, for example, FIG. 10. Each switch setter 9A can selectively provide, for example, either the first signal or the second signal to one of the switches 7 connected to the switch setter 9A. Each switch setter 9A can provide, for example, the second signal to one of the switches 7 connected to the switch setter 9A in response to a signal (also referred to as a specific signal) corresponding to the switch setter 9A provided from a specific signal line group 90. This reduces image quality degradation resulting from any broken drive signal line 3 outside the image display unit 20 in the display device 100, without, for example, detailed operations such as cutting the specific wire portion 9P.

In this example, the switch setters 9A are n switch setters 9A, as illustrated in FIG. 10. More specifically, the n switch setters 9A include, for example, a first switch setter 9A1, a second switch setter 9A2, a third switch setter 9A3, . . . , and an n-th switch setter 9An. For example, the first switch 71 is connected to the first switch setter 9A1. For example, the second switch 72 is connected to the second switch setter 9A2. For example, the third switch 73 is connected to the third switch setter 9A3. For example, the n-th switch 7n is connected to the n-th switch setter 9An. The display device 100 includes, for example, the specific signal line group 90 including multiple signal lines (also referred to as specific signal lines) L1. The specific signal line group 90 is, for example, connected to the drive 30. The drive 30 can, for example, provide specific signals to the specific signal line group 90. In this example, the signals corresponding to the respective switch setters 9A are multiple specific signals. The multiple specific signals correspond to, for example, pieces of specific identification information assigned to the respective switch setters 9A.

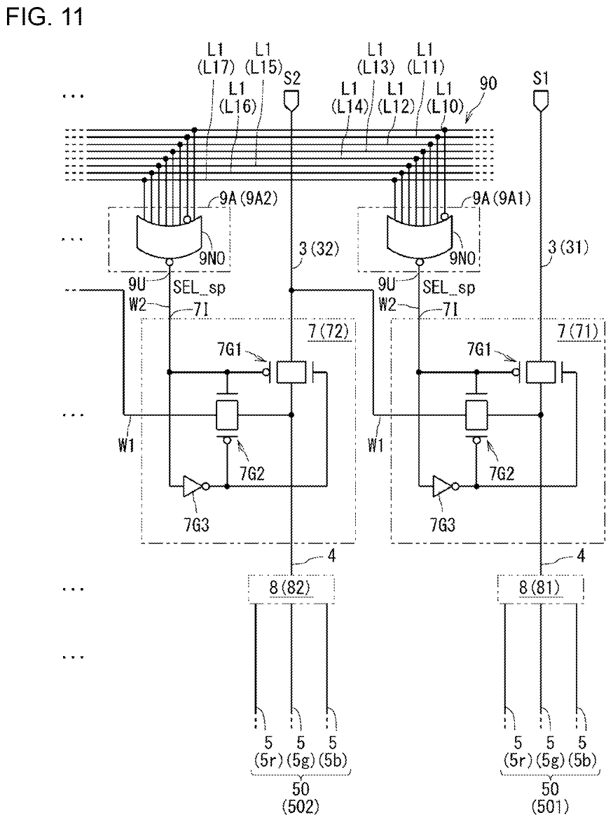

FIG. 11 is a circuit diagram of example switches 7 and switch setters 9A in a second embodiment. FIG. 11 illustrates the first switch 71 as a first switch 7, the first switch setter 9A1 as a first switch setter 9A, the second switch 72 as a second switch 7, and the second switch setter 9A2 as a second switch setter 9A.

As illustrated in FIG. 11, each switch setter 9A includes, for example, a NOR gate 9NO and a signal output section 9U.

In this example, at least two switch setters 9A are each assigned with an address (also referred to as a specific address) as specific identification information. The specific addresses assigned to two or more pixel columns C1 may be, for example, assigned to the switch setters 9A corresponding to the two or more pixel columns C1. In the example below, a specific address is assigned to each switch setter 9A. The number of switch setters 9A is 2 to the y-th power minus 1 (y is a natural number greater than or equal to 2). In this example, a specific address in y bits for x in a binary number is assigned to an x-th switch setter 9Ax. For example, when the natural number y is 8, the number of switch setters 9A is 255, which is 2 to the eighth power minus 1. A specific address in eight bits is assigned to each of the 255 switch setters 9A. More specifically, the first switch setter 9A1 is assigned with, for example, a specific address of 00000001. The second switch setter 9A2 is assigned with, for example, a specific address of 00000010. The third switch setter 9A3 is assigned with, for example, a specific address of 00000011. The 255th switch setter 9A255 is assigned with, for example, a specific address of 11111111.

The specific signal line group 90 includes, for example, y specific signal lines L1. In this case, the specific signal line group 90 can transmit, for example, a L signal or a H signal using the y specific signal lines L1 to transmit signals (specific signals) corresponding to the specific addresses in y bits. In this example, the specific signal line group 90 can transmit signals of 2 to the yth power patterns. The signals of 2 to the yth power patterns include, for example, (2y−1) specific signals corresponding to (2y−1) specific addresses corresponding to (2y−1) switch setters 9A corresponding to the number being 2 to the y-th power minus 1 and include one signal (also referred to as an unspecific signal) corresponding to none of the specific addresses of the (2y−1) switch setters 9A. The numbers 0 and 1 in each digit of the (2y−1) specific addresses can be represented by, for example, a L signal and a H signal transmitted from each of the y specific signal lines L1.

In the example in FIG. 11, the natural number y is 8. The specific signal line group includes eight specific signal lines L1. The eight specific signal lines L1 are a first specific signal line L10, a second specific signal line L11, a third specific signal line L12, a fourth specific signal line L13, a fifth specific signal line L14, a sixth specific signal line L15, a seventh specific signal line L16, and an eighth specific signal line L17. In this example, the specific signal line group 90 can transmit, for example, a L signal or a H signal with each of the eight specific signal lines L1 to transmit a specific signal corresponding to each specific address in 8 bits. In this example, the specific signal line group 90 can transmit signals of 255 patterns or signals of 2 to the eighth power patterns. The signals of 256 patterns include 255 specific signals corresponding to 255 specific addresses corresponding to the 255 switch setters 9A, and one unspecific signal corresponding to none of the 255 switch setters 9A. The numbers 0 and 1 in each digit in the 255 specific addresses in eight bits can be represented by, for example, a L signal and a H signal transmitted from each of the eight specific signal lines L1 of the first specific signal line L10 to the eighth specific signal line L17.

More specifically, 0 in the first digit of a specific address can be represented by a L signal transmitted from the first specific signal line L10, and 1 in the first digit of a specific address can be represented by a H signal transmitted from the first specific signal line L10. For example, 0 in the second digit of a specific address can be represented by a L signal transmitted from the second specific signal line L11, and 1 in the second digit of a specific address can be represented by a H signal transmitted from the second specific signal line L11. For example, 0 in the third digit of a specific address can be represented by a L signal transmitted from the third specific signal line L12, and 1 in the third digit of a specific address can be represented by a H signal transmitted from the third specific signal line L12. For example, 0 in the fourth digit of a specific address can be represented by a L signal transmitted from the fourth specific signal line L13, and 1 in the fourth digit of a specific address can be represented by a H signal transmitted from the fourth specific signal line L13. For example, 0 in the fifth digit of a specific address can be represented by a L signal transmitted from the fifth specific signal line L14, and 1 in the fifth digit of a specific address can be represented by a H signal transmitted from the fifth specific signal line L14. For example, 0 in the sixth digit of a specific address can be represented by a L signal transmitted from the sixth specific signal line L15, and 1 in the sixth digit of a specific address can be represented by a H signal transmitted from the sixth specific signal line L15. For example, 0 in the seventh digit of a specific address can be represented by a L signal transmitted from the seventh specific signal line L16, and 1 in the seventh digit of a specific address can be represented by a H signal transmitted from the seventh specific signal line L16. For example, 0 in the eighth digit of a specific address can be represented by a L signal transmitted from the eighth specific signal line L17, and 1 in the eighth digit of a specific address can be represented by a H signal transmitted from the eighth specific signal line L17.

Each of the (2y−1) switch setters 9A includes its input section of the NOR gate 9NO connected to, for example, wires branching from the y specific signal lines L1 included in the specific signal line group 90. In the example in FIG. 11, each of the 255 switch setters 9A includes its input end of the NOR gate 9NO connected to wires branching from eight specific signal lines L1 included in the specific signal line group 90.

The input end of the NOR gate 9NO in each of the (2y−1) switch setters 9A includes, for example, a NOT circuit in a portion electrically connected to the specific signal lines L1 each corresponding a digit of all the digits corresponding to 1, which are included in the specific address in y bits assigned to the switch setter 9A. Each switch setter 9A thus changes, for example, with the NOT circuit at the input end of the NOR gate 9NO, all the input signals into the NOR gate 9NO from the y specific signal lines L1 to L signals in response to the specific signal corresponding to the specific address in y bits assigned to the switch setter 9A being input from the specific signal line group 90. The NOR gate 9NO then outputs a H signal, and the signal output section 9U outputs the H signal to the signal input section 7I in the corresponding switch 7. In contrast, in response to a specific signal or an unspecific signal not corresponding to the specific address assigned to the switch setter 9A being input from the specific signal line group 90, each switch setter 9A does not change, with the NOT circuit at the input end of the NOR gate 9NO, all the input signals into the NOR gate 9NO from the y specific signal lines L1 to L signals. The NOR gate 9NO then outputs a L signal, and the signal output section 9U outputs the L signal to the signal input section 7I in the corresponding switch 7.

In the example in FIG. 11, the input end of the NOR gate 9NO in each of the 255 switch setters 9A includes a NOT circuit in a portion electrically connected to the specific signal lines L1 each corresponding a digit of all the digits corresponding to 1, which are included in the specific address in eight bits assigned to the switch setter 9A. Each switch setter 9A thus changes, for example, with the NOT circuit at the input end of the NOR gate 9NO, all the input signals into the NOR gate 9NO from the eight specific signal lines L1 (specifically, the first to eighth specific signal lines L10 to L17) to L signals in response to the specific signal corresponding to the specific address in eight bits assigned to the switch setter 9A being input from the specific signal line group 90. The NOR gate 9NO then outputs a H signal. The signal output section 9U thus outputs the H signal to the signal input section 7I in the corresponding switch 7. In contrast, in response to a specific signal or an unspecific signal not corresponding to the specific address assigned to the switch setter 9A being input from the specific signal line group 90, each switch setter 9A does not change, with the NOT circuit at the input end of the NOR gate 9NO, all the input signals into the NOR gate 9NO from the eight specific signal lines L1 (specifically, the first to eighth specific signal lines L10 to L17) to L signals. The NOR gate 9NO then outputs a L signal. The signal output section 9U thus outputs the L signal to the signal input section 7I in the corresponding switch 7.

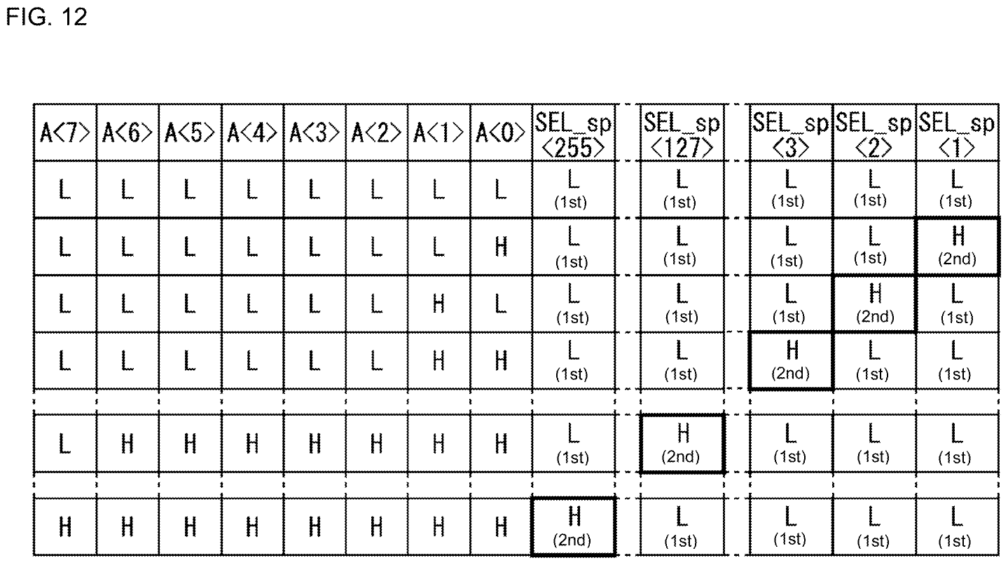

FIG. 12 is a truth table showing the relationships between the patterns of signals input into the 255 switch setters 9A from the specific signal line group 90 and signals output from the switch setters 9A. In FIG. 12, L represents a L signal and H represents a H signal for a signal A<0> transmitted from the first specific signal line L10, a signal A<1> transmitted from the second specific signal line L11, a signal A<2> transmitted from the third specific signal line L12, a signal A<3> transmitted from the fourth specific signal line L13, a signal A<4> transmitted from the fifth specific signal line L14, a signal A<5> transmitted from the sixth specific signal line L15, a signal A<6> transmitted from the seventh specific signal line L16, and a signal A<7> transmitted from the eighth specific signal line L17. In FIG. 12, L represents a L signal and H represents a H signal for a signal SEL_sp<x> output from the x-th switch setter 9Ax. FIG. 12 shows an unspecific signal not corresponding to the fixed address of any of the switch setters 9A being input and H signals output from the first switch setter 9A1, the second switch setter 9A2, the third switch setter 9A3, . . . , the 127th switch setter 9A127, . . . , and the 255th switch setter 9A255. The signals for other switch setters are not shown for ease of explanation and due to the size of the drawing.

As shown in FIG. 12, when, for example, the signals A<0> to A<7> are all L signals, the first switch setter 9A1 to the 255th switch setter 9A255 all output L signals. When, for example, the signal A<0> is a H signal and the signals A<1> to A<7> are all L signals, the first switch setter 9A1 outputs a H signal. When, for example, the signal A<1> is a H signal and the signal A<0> and the signals A<2> to A<7> are all L signals, the second switch setter 9A2 outputs a H signal. When, for example, the signals A<0> and A<1> are H signals and the signals A<2> to A<7> are all L signals, the third switch setter 9A3 outputs a H signal. When, for example, the signals A<0> to A<6> are all H signals and the signal A<7> is a L signal, the 127th switch setter 9A127 outputs a H signal. When, for example, the signals A<0> to A<7> are all H signals, the 255th switch setter 9A255 outputs a H signal.

In this manner, each of the 255 switch setters 9A can provide, for example, a H signal as the second signal to one of the switches 7 connected to the switch setter 9A in response to the specific signal corresponding to the switch setter 9A from the multiple specific signal lines L1. For example, one of the multiple switches 7 receiving an input L signal as the first signal from the corresponding switch setter 9A is set to the first conductive state. For example, one of the multiple switches 7 receiving an input H signal as the second signal from the corresponding switch setter 9A is set to the second conductive state. This structure reduces image quality degradation resulting from any broken drive signal line 3 outside the image display unit 20 in the display device 100 without, for example, detailed operations such as cutting the specific wire portion 9P.

Such a switch 7 can be set to the second conductive state by, for example, storing, into the storage in the drive 30, information about the specific address corresponding to a pixel column C1 with a dark line or a bright line identified in the inspection or maintenance performed before the shipment of the display device 100. The storage in the drive 30 is, for example, a non-volatile memory.

In the example in FIG. 12, for the signal SEL_sp<x> output from the x-th switch setter 9Ax being a L signal, the switch 7 receiving the input L signal is set to the first conductive state, as indicated by (1st). In FIG. 12, for the signal SEL_sp<x> output from the x-th switch setter 9Ax being a H signal, the switch 7 receiving the input H signal is set to the second conductive state, as indicated by (2nd). In the example structure illustrated in FIG. 11, when, for example, the signal SEL_sp<1> output from the first switch setter 9A1 is a L signal as the first signal, the first switch 71 receiving this L signal is set to provide, from the first drive signal line 31 as the normal drive signal line 3, an image signal S1 to the emission control signal lines 5 in the first emission control signal line group 501 (set to the first conductive state). When, for example, the signal SEL_sp<1> output from the first switch setter 9A1 is a H signal as the second signal, the first switch 71 receiving this H signal is set to provide, from the second drive signal line 32 as the additional drive signal line, an image signal S2 to the emission control signal lines 5 in the first emission control signal line group 501 (set to the second conductive state).

### 2-2. Third Embodiment

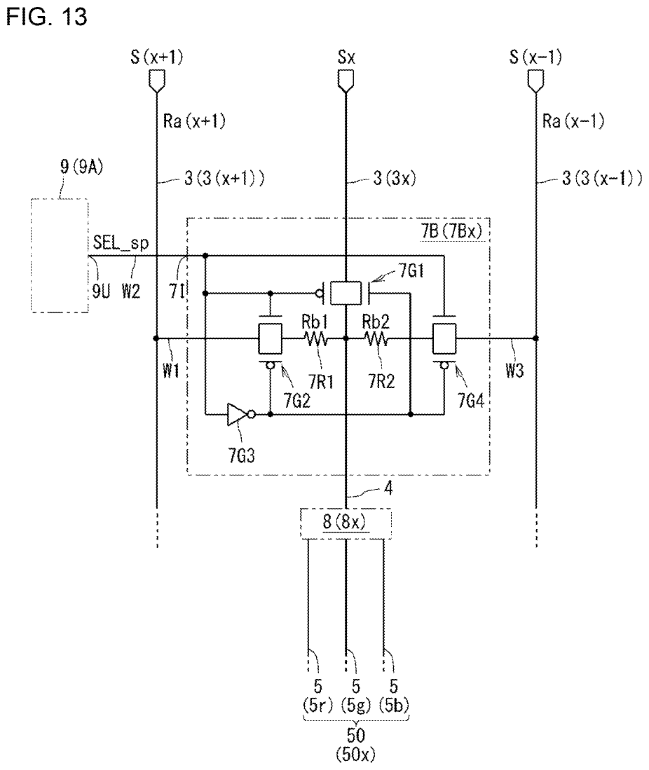

In each of the first embodiment and the second embodiment, as illustrated in, for example, FIG. 13, the switches 7 may be replaced with switches 7B each connected to one normal drive signal line 3 and at least two drive signal lines 3 as at least one additional drive signal line 3 among the multiple drive signal lines 3. In this case, for example, at least one additional drive signal line 3 connected to the corresponding switch 7B includes at least two additional drive signal lines 3 among the multiple drive signal lines 3. Each switch 7B provides, for example, in the first conductive state, an image signal from the drive 30 through one normal drive signal line 3 to the corresponding ones of the multiple emission control signal lines 5. Each switch 7B provides, for example, in the second conductive state, an image signal from the drive 30 through at least two additional drive signal lines 3 different from one normal drive signal line 3 to corresponding ones of the multiple emission control signal lines 5. Each switch 7B may provide, for example, in the second conductive state, an image signal with a voltage between the voltages of at least two image signals provided respectively to at least two additional drive signal lines 3 from the drive 30 to the corresponding ones of the multiple emission control signal lines 5. The image signal with a voltage between the voltages of at least two image signals is, for example, an image signal with an average voltage of the voltages of at least two image signals.

In the present embodiment, for example, at least two additional drive signal lines 3 connected to the corresponding switch 7B are drive signal lines 3 located adjacent to one of the multiple drive signal lines 3 connected to the switch 7B. More specifically, for example, at least two additional drive signal lines 3 connected to the corresponding switch 7B are drive signal lines 3 located on both sides of one of the multiple drive signal lines 3 connected to the switch 7B. In other words, for example, the normal drive signal line 3 and the two additional drive signal lines 3 connected to the corresponding switch 7B correspond to one normal drive signal line 3 for one pixel column C1 and two normal drive signal lines 3 for the two pixel columns C1 located on both sides of the pixel column C1. An example structure for the second switch 72 will be described. One normal drive signal line 3 connected to the second switch 72 serves as, for example, the second drive signal line 32 being one normal drive signal line 3 for the second pixel column C12. The two additional drive signal lines 3 connected to the second switch 72 serve as, for example, the first drive signal line 31 and the third drive signal line 33 being the two normal drive signal lines 3 for the first pixel column C11 and the third pixel column C13 located on both sides of the second pixel column C12. This structure allows, for example, multiple pixel units 2, which are otherwise to emit light in response to an image signal provided from the drive 30 through the normal drive signal line 3, to emit light at a luminance level between the luminance levels of the pixel units 2 on both sides the pixel unit 2 when the normal drive signal line 3 breaks. The luminance level between the luminance levels of the pixel units 2 on both sides of the pixel unit 2 is, for example, the average of the luminance levels of the pixel units 2 on both sides of the pixel unit 2. The pixel units 2 are thus less noticeable.

FIG. 13 is a circuit diagram of an example switch 7B in the display device 100 according to a third embodiment. The switch 7B is, for example, a variation of the switch 7 in the first embodiment and the second embodiment. The switch 7B further includes a fourth gate 7G4, a first resistor 7R1, and a second resistor 7R2. In other words, an x-th switch 7Bx is, for example, a variation of the x-th switch 7x in the first embodiment and the second embodiment, and further includes the fourth gate 7G4, the first resistor 7R1, and the second resistor 7R2.

The fourth gate 7G4 is, for example, located on a wire connecting the (x−1)th drive signal line 3(x−1) and the x-th selector 8x. The (x−1)th drive signal line 3(x−1) as one additional drive signal line 3 is connected to the x-th switch 7Bx with a connection wire W3. The fourth gate 7G4 is settable to a conductive state to allow, for example, an image signal based on the image signal S(x−1) to be provided from the (x−1)th drive signal line 3(x−1) to the emission control signal lines 5 in the x-th emission control signal line group 50x in response to one or more particular signals being input. The fourth gate 7G4 is, for example, a TG. In this case, the fourth gate 7G4 includes the input fifth electrode connected to the (x−1)th drive signal line 3(x−1) and the output sixth electrode connected to the emission control signal lines 5 through the x-th selector 8x. The fourth gate 7G4 allows a current to flow through the fifth electrode and the sixth electrode (shifts to a conductive state) in response to an input low-potential signal (L signal) into the gate electrode of the p-channel transistor and an input high-potential signal (H signal) into the gate electrode of the n-channel transistor. In this state, for example, an image signal based on the image signal S(x−1) can be provided from the (x−1)th drive signal line 3(x−1) to the emission control signal lines 5 in the x-th emission control signal line group 50x through the fourth gate 7G4.

The fourth gate 7G4 includes the gate electrode of the n-channel transistor connected to, for example, the signal input section 7I and the gate electrode of the p-channel transistor connected to the output section of the third gate 7G3. The signals input into the signal input section 7I are thus, for example, provided to the gate electrode of the p-channel transistor of the first gate 7G1, the gate electrode of the n-channel transistor of the second gate 7G2, the input end of the third gate 7G3, and the gate electrode of the n-channel transistor of the fourth gate 7G4.

The first resistor 7R1 is located on, for example, a wire connecting a wire connecting the first gate 7G1 and the x-th selector 8x and the output fourth electrode of the second gate 7G2. The first resistor 7R1 has, for example, a first electrical resistance Rb1. The first electrical resistance Rb1 is set to be much higher than, for example, the electrical resistance Ra(x+1) at the (x+1)th drive signal line 3(x+1) as an additional drive signal line 3 connected to the input third electrode of the second gate 762. The first electrical resistor Rb1 can attenuate, for example, the voltage of the image signal S(x+1) input from the (x+1)th drive signal line 3(x+1) through the second gate 7G2 to transmit the attenuated image signal to the wire connecting the first gate 7G1 and the x-th selector 8x.

The second resistor 7R2 is located on, for example, a wire connecting the wire connecting the first gate 7G1 and the x-th selector 8x and the output sixth electrode of the fourth gate 7G4. The second resistor 7R2 has, for example, a second electrical resistance Rb2. The second electrical resistance Rb2 is set to be much higher than, for example, the electrical resistance Ra(x−1) at the (x−1)th drive signal line 3(x−1) as an additional drive signal line 3 connected to the input fifth electrode of the fourth gate 7G4. The second electrical resistance Rb2 can attenuate, for example, the voltage of the image signal S(x−1) input from the (x−1)th drive signal line 3(x−1) through the fourth gate 7G4 to transmit the attenuated image signal to the wire connecting the first gate 7G1 and the x-th selector 8x.

In one example, a L signal is input into the signal input section 7I in the x-th switch 7Bx with the above structure. In this example, the first gate 7G1 receives an input L signal into the gate electrode of the p-channel transistor and an input H signal into the gate electrode of the n-channel transistor. The first gate 7G1 thus allows, for example, a current to flow through the first electrode and the second electrodes (or shifts to a conductive state). Each of the second gate 7G2 and the fourth gate 7G4 receives, for example, an input H signal into the gate electrode of the p-channel transistor and an input L signal into the gate electrode of the n-channel transistor. The second gate 7G2 thus blocks, for example, the current flowing through the third electrode and the fourth electrode (or shifts to a non-conductive state), and the fourth gate 7G4 blocks the current flowing through the fifth electrode and the sixth electrode (shifts to a non-conductive state). The x-th switch 7Bx is thus set to a state (first conductive state) in which the image signal Sx can be provided from the x-th drive signal line 3x to the emission control signal lines 5 in the x-th emission control signal line group 50x through the first gate 7G1.

In one example, a H signal is input into the signal input section 7I in the x-th switch 7Bx with the above structure. In this example, the first gate 7G1 receives an input H signal into the gate electrode of the p-channel transistor and an input L signal into the gate electrode of the n-channel transistor. The first gate 7G1 thus blocks, for example, the current flowing through the first electrode and the second electrode (or shifts to a non-conductive state). Each of the second gate 7G2 and fourth gate 7G4 receives, for example, an input L signal into the gate electrode of the p-channel transistor and an input H signal into the gate electrode of the n-channel transistor. The second gate 7G2 thus allows, for example, a current to flow through the third electrode and the fourth electrode (or shifts to a conductive state), and the fourth gate 7G4 allows a current to flow through the fifth electrode and the sixth electrode (shifts to a conductive state). The x-th switch 7Bx thus allows, for example, an image signal with a voltage between the voltage of the image signal S(x+1) input from the (x+1)th drive signal line 3(x+1) through the second gate 7G2 and the voltage of the image signal S(x−1) input from the (x−1)th drive signal line 3(x−1) through the fourth gate 7G4 to be provided to the emission control signal lines 5 in the x-th emission control signal line group 50x (or shifts to the second conductive state). The first electrical resistance Rb1 and the second electrical resistance Rb2 may be, for example, set as appropriate to provide the image signal with a voltage between the voltages of the image signal S(x+1) and the image signal S(x−1) to the emission control signal lines 5 in the x-th emission control signal line group 50x. The first electrical resistance Rb1 and the second electrical resistance Rb2 may be, for example, set to substantially the same and appropriate electrical resistance to provide an image signal with an average voltage of the image signal S(x+1) and the image signal S(x−1) to the emission control signal lines 5 in the x-th emission control signal line group 50x.

In the second conductive state, for example, the first electrical resistance Rb1 and the second electrical resistance Rb2 increase the time constants for the capacitive elements in the light emission controllers in the first subpixel 2r, the second subpixel 2g, and the third subpixel 2b. The structure including the switches 7B in the example in FIG. 13 is thus likely to be used for a display device 100 with longer intervals of image switching (or with a lower frame rate).

### 2-3. Fourth Embodiment

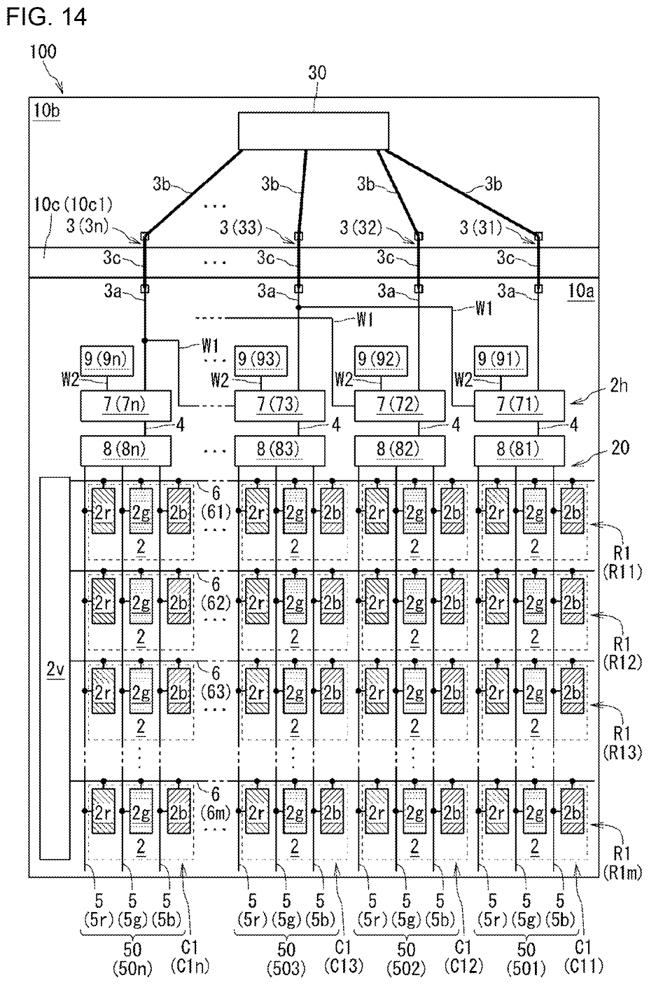

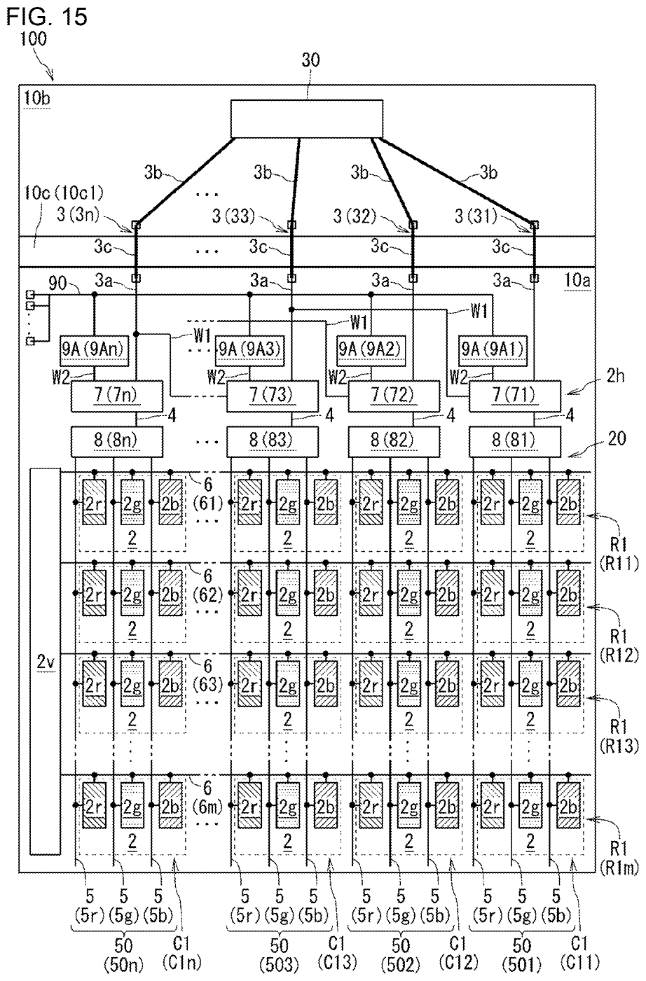

In each of the first embodiment and the second embodiment, as illustrated in, for example, FIGS. 14 and 15, one additional drive signal line 3 connected to the corresponding switch 7 may be a drive signal line 3 other than a drive signal line 3 located adjacent to one of the normal drive signal lines 3 connected to the switch 7. In other words, one normal drive signal line 3 and one additional drive signal line 3 connected to a switch 7 are, for example, two normal drive signal lines 3 for two pixel columns C1 that are not adjacent to each other. This structure allows, for any broken normal drive signal line 3 for providing image signals to the emission control signal lines 5 and any broken drive signal line 3 adjacent to the normal drive signal line 3, the switches 7 in the image display unit 20 to provide image signals to the emission control signal lines 5 through another drive signal line 3. The display device 100 is thus less likely to be dark (have a dark line) or have high luminance (have a bright line) in one pixel column C1 with no image signals provided to the column. The display device 100 can thus reduce image quality degradation resulting from a broken drive signal line 3 outside the image display unit 20 in any situation in which drive line signals 3 adjacent to each other are likely to break.

FIG. 14 is a schematic block diagram of a display device 100 with a first example structure according to a fourth embodiment. The display device 100 illustrated in FIG. 14 includes the structure that is a variation of, for example, the structure of the display device 100 according to the first embodiment illustrated in FIG. 5, with a drive signal line 3 that is not adjacent to the normal drive signal line 3 being connected to each switch 7, in place of one additional drive signal line 3 connected to the corresponding switch 7.

FIG. 15 is a schematic block diagram of a display device 100 with a second example structure according to the fourth embodiment. The display device 100 illustrated in FIG. 15 includes the structure that is a variation of, for example, the structure of the display device 100 according to the second embodiment illustrated in FIG. 10, with a drive signal line 3 that is not adjacent to the normal drive signal line 3 connected to each switch 7, in place of one additional drive signal line 3 connected to the corresponding switch 7.

In the third embodiment, for example, at least two additional drive signal lines 3 connected to the corresponding switch 7B may be drive signal lines 3 that are not adjacent to the normal drive signal line 3 among the multiple drive signal lines 3 connected to the switch 7B. This structure allows, for any broken normal drive signal line 3 for providing image signals to the emission control signal lines 5 and any broken drive signal line 3 adjacent to the normal drive signal line 3, the switches 7B in the image display unit 20 to provide image signals to the emission control signal lines 5 through at least two additional drive signal lines 3. The display device 100 is thus less likely to be dark (have a dark line) or have high luminance (have a bright line) in one pixel column C1 with no image signals provided to the column. The display device 100 can thus reduce image quality degradation resulting from a broken drive signal line 3 outside the image display unit 20 in any situation in which drive line signals 3 adjacent to each other are likely to break.

### 2-4. Fifth Embodiment

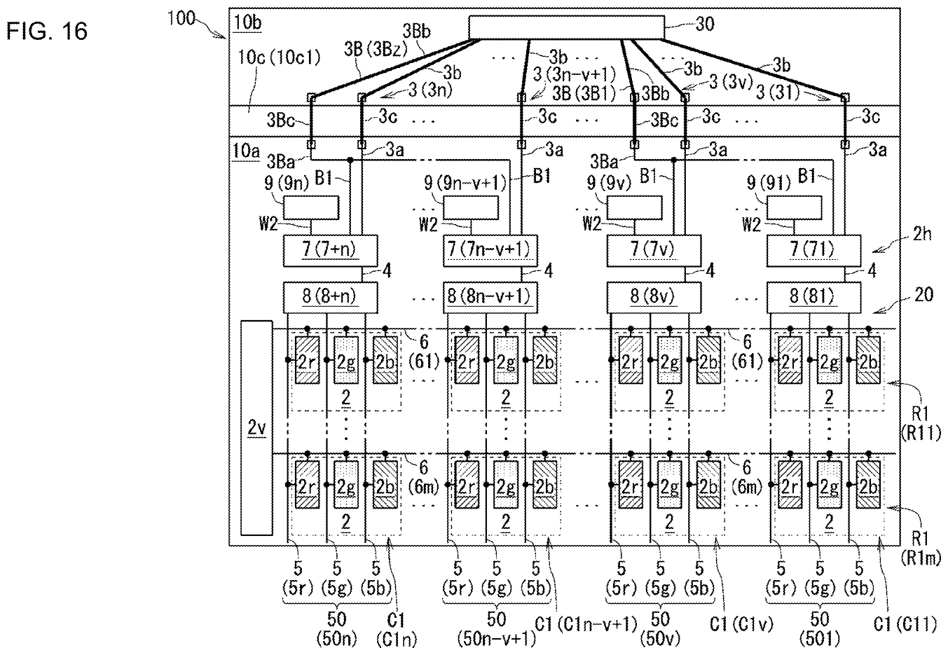

In each of the first embodiment and the second embodiment, as illustrated in, for example, FIGS. 16 to 20, one additional drive signal line 3 connected to the corresponding switch 7 may be replaced with one drive signal line (also referred to as a redundant drive signal line) 3B located separately, as a standby line, from the multiple drive signal lines 3. The redundant drive signal line 3B can have image signals provided from the drive 30. This structure allows, for any broken normal drive signal line 3 for providing image signals to the emission control signal lines 5, the switches 7 in the image display unit 20 to provide image signals to the emission control signal lines 5 through the redundant drive signal line 3B being an additional drive signal line. This allows, for example, the display device 100 to have substantially no image quality degradation resulting from a broken drive signal line 3 outside the image display unit 20. The display device 100 can thus have less image quality degradation resulting from a broken drive signal line 3 outside the image display unit 20.

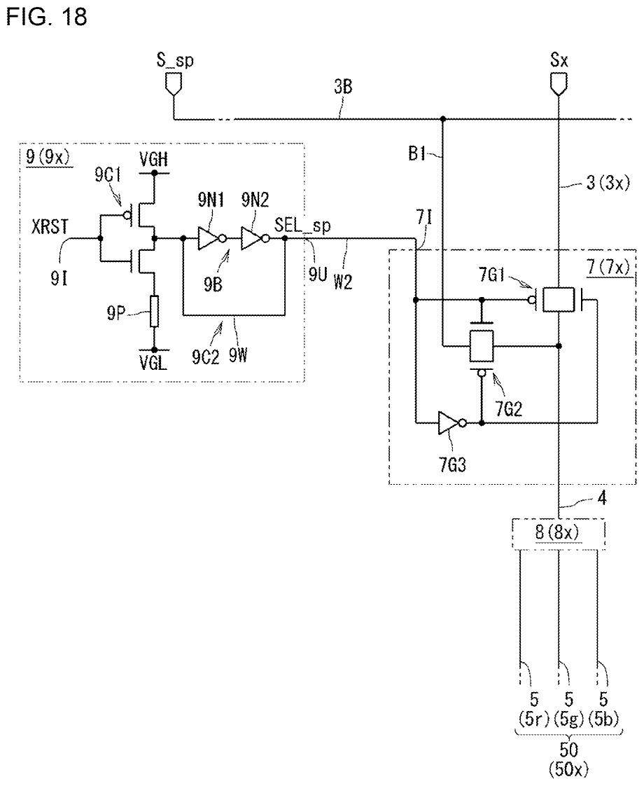

FIG. 16 is a schematic block diagram of a display device 100 with a first example structure according to a fifth embodiment. The display device 100 illustrated in FIG. 16 includes the structure that is a variation of, for example, the structure of the display device 100 according to the first embodiment illustrated in FIG. 5, with the redundant drive signal line 3B connected to each switch 7 in place of one additional drive signal line 3. FIG. 18 is a circuit diagram of a switch 7 and a switch setter 9 with a first example structure in the fifth embodiment. The switch 7 and the switch setter 9 illustrated in FIG. 18 are variations of, for example, the switch 7 and switch setter 9 in the first embodiment illustrated in FIG. 7, with the redundant drive signal line 3B connected to the x-th switch 7x in place of the (x+1)th drive signal line 3(x+1). In this example, the x-th switch 7x set to the second conductive state can provide the image signal S_sp from the redundant drive signal line 3B as an additional drive signal line to the emission control signal lines 5 in the x-th emission control signal line group 50x. The image signal S_sp provided from the drive 30 to the emission control signal lines 5 through the redundant drive signal line 3B corresponds to, for example, the image signal Sx to be provided to the emission control signal lines 5 through the x-th drive signal line 3x as the otherwise normal drive signal line 3. This allows, when the normal drive signal line 3 breaks, for example, image signals that are otherwise to be provided to multiple pixel units 2 through the normal drive signal line 3 to be provided to the multiple pixel units 2 through the redundant drive signal line 3B. The display device 100 displaying relatively low resolution images thus causes less visible light emission defects resulting from any broken normal drive signal line 3.

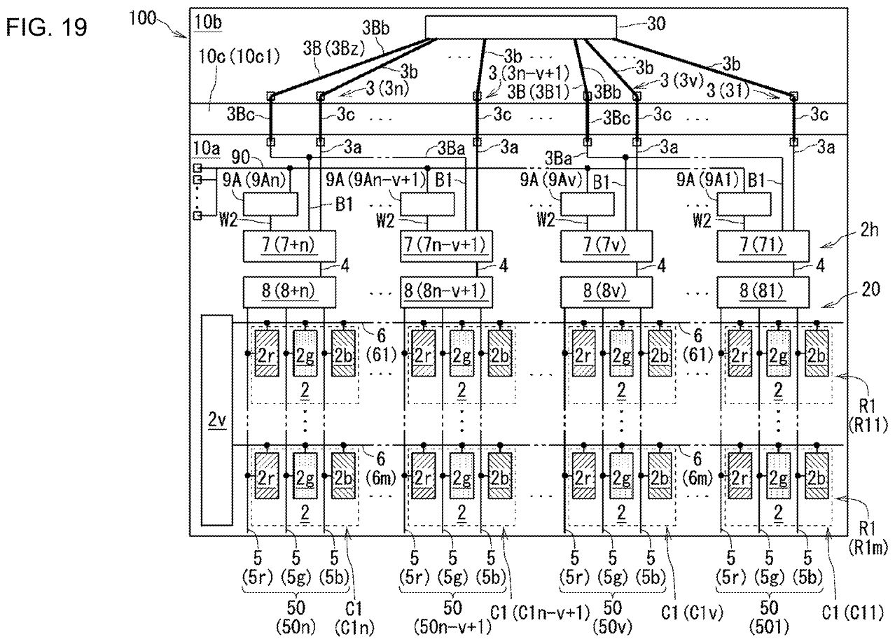

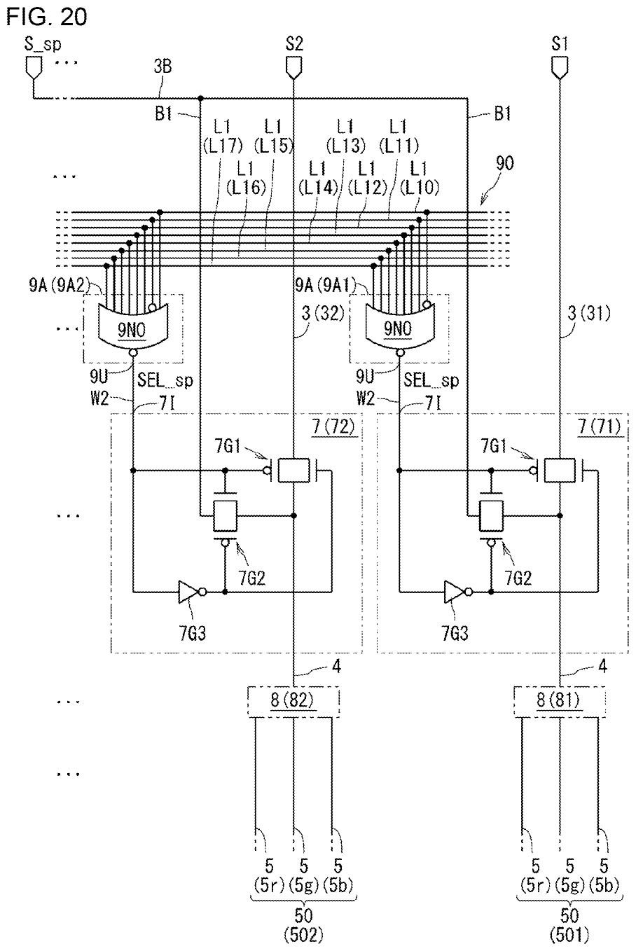

FIG. 19 is a schematic block diagram of a display device 100 with a second example structure according to the fifth embodiment. The display device 100 illustrated in FIG. 19 includes the structure that is a variation of, for example, the structure of the display device 100 according to the second embodiment illustrated in FIG. 10, with a redundant drive signal line 3B connected to each switch 7 in place of one additional drive signal line 3. FIG. 20 is a circuit diagram of switches 7 and switch setters 9 with second example structures in the fifth embodiment. Each switch 7 and each switch setter 9 illustrated in FIG. 20 are variations of, for example, the switch 7 and the switch setter 9 in the second embodiment illustrated in FIG. 11, with the redundant drive signal line 3B connected to the first switch 71 in place of the second drive signal line 32. In this example, the first switch 71 set to the second conductive state can provide the image signal S_sp from the redundant drive signal line 3B as an additional drive signal line to the emission control signal lines 5 in the first emission control signal line group 501. The image signal S_sp provided from the drive 30 to the emission control signal lines 5 through the redundant drive signal line 3B corresponds to, for example, the image signal S1 to be provided to the emission control signal lines 5 through the first drive signal line 31 as the otherwise normal drive signal line 3. This allows, when the normal drive signal line 3 breaks, for example, image signals that are otherwise to be provided to multiple pixel units 2 through the normal drive signal line 3 to be provided to the multiple pixel units 2 through the redundant drive signal line 3B. The display device 100 displaying relatively low resolution images thus causes less visible light emission defects resulting from any broken normal drive signal line 3.

As illustrated in, for example, FIGS. 16 and 19, the display device 100 according to the fifth embodiment includes multiple redundant drive signal lines 3B each located for every two or more drive signal lines 3 among the multiple drive signal lines 3. The drive 30 can provide, for example, image signals to each of the multiple redundant drive signal lines 3B.

Each redundant drive signal lines 3B includes, for example, a first redundant wire portion 3Bb, a second redundant wire portion 3Bc, and a third redundant wire portion 3Ba. For example, the first redundant wire portion 3Bb (back wire portion) is located on the second surface 10b. For example, the second redundant wire portion 3Bc (side wire portion) is located on the side surface 10c. For example, the third redundant wire portion 3Ba (front wire portion) is located on the first surface 10a. The first redundant wire portion 3Bb is connected to, for example, the drive 30. Each redundant drive signal line 3B includes, for example, the first redundant wire portion 3Bb, the second redundant wire portion 3Bc, and the third redundant wire portion 3Ba connected in series in the stated order. More specifically, the first redundant wire portion 3Bb is connected to, for example, a conductive third connection portion located along the side surface 10c on the second surface 10b. The second redundant wire portion 3Bc is connected to the third connection portion and to, for example, a conductive fourth connection portion located along the side surface 10c on the first surface 10a. The third redundant wire portion 3Ba is connected to, for example, the fourth connection portion. In this case, each redundant drive signal line 3B includes, for example, the first redundant wire portion 3Bb, the third connection portion, the second redundant wire portion 3Bc, the fourth connection portion, and the third redundant wire portion 3Ba connected in the stated order. Each of the third connection portion and the fourth connection portion is, for example, a conductor pad, in the same manner as or similarly to the first connection portion and the second connection portion described above.

In the same manner as or similarly to the second wire portion 3c described above, the second redundant wire portion 3Bc may be formed by, for example, drying and firing, with heat, a conductive paste applied to the side surface 10c in a predetermined pattern, or curing the conductive paste on the side surface 10c with heat, with light such as UV rays, or with a combination of heat and light. The second redundant wire portion 3Bc may be formed by, for example, a thin film formation method such as plating, vapor deposition, or CVD. The side surface 10c of the substrate 10 may include grooves extending from the first surface 10a to the second surface 10b in portions to receive the second redundant wire portions 3Bc. In this case, the conductive paste can be easily applied to the grooves as intended areas on the side surface 10c.

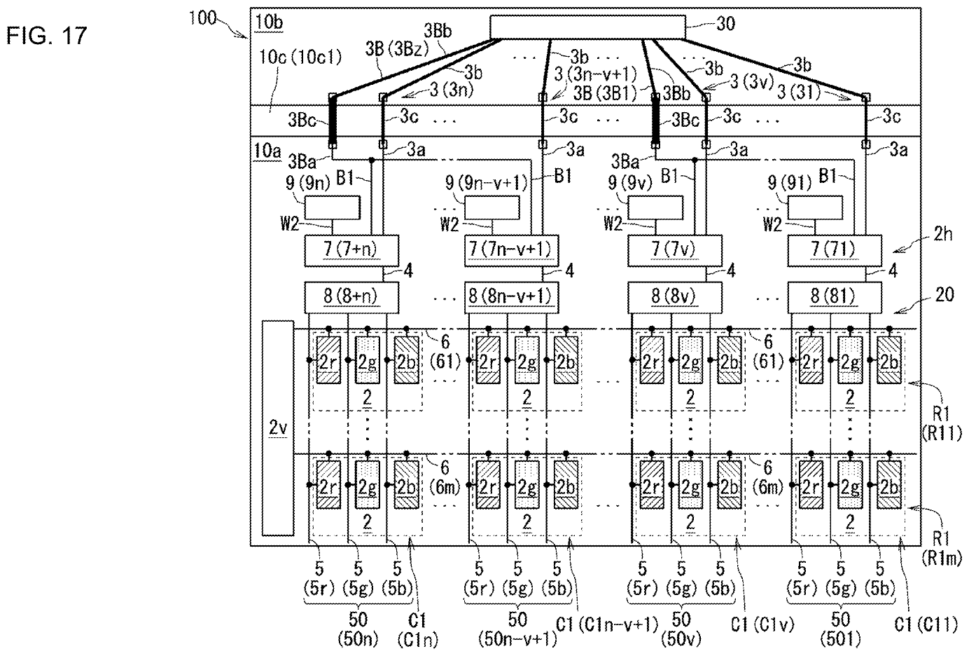

The second redundant wire portion 3Bc in each redundant drive signal line 3B may be wider and/or thicker than either the first redundant wire portion 3Bb or the third redundant wire portion 3Ba. The second redundant wire portion 3Bc, formed by applying and firing the conductive paste, is likely to have a greater resistance than the first redundant wire portion 3Bb and the third redundant wire portion 3Ba formed by a thin film formation method, when the redundant wire portions have the same thickness. The resistance of the second redundant wire portion 3Bc is thus reduced to be easily matched with the resistances of the first redundant wire portion 3Bb and the third redundant wire portion 3Ba. More specifically, the structure can reduce any increase in connection resistance (contact resistance) between the second redundant wire portion 3Bc and each of the first redundant wire portion 3Bb and the third redundant wire portion 3Ba. As illustrated in, for example, FIG. 17, the second redundant wire portion 3Bc may be wider than either the first redundant wire portion 3Bb or the third redundant wire portion 3Ba. The width of the second redundant wire portion 3Bc may be more than once and about five times or less the width of each of the first redundant wire portion 3Bb and the third redundant wire portion 3Ba, but is not limited to this range. In this structure, the thickness of the second redundant wire portion 3Bc may be greater than or equal to the thickness of each of the first redundant wire portions 3Bb and third redundant wire portion 3Ba.

For the same purpose, when the first redundant wire portion 3Bb, the second redundant wire portion 3Bc, and the third redundant wire portion 3Ba have the same width, the second redundant wire portion 3Bc may have a thickness greater than the thickness of each of the first redundant wire portion 3Bb and the third redundant wire portion 3Ba. The second redundant wire portion 3Bc may have a thickness more than once and about 10 times or less the thickness of each of the first redundant wire portion 3Bb and the third redundant wire portion 3Ba, but the thickness is not limited to this range.

For the same purpose, the second redundant wire portion 3Bc may be wider and thicker than either the first redundant wire portion 3Bb or the third redundant wire portion 3Ba. For the same purpose as well, the second redundant wire portion 3Bc may be shorter than either the first redundant wire portion 3Bb or the third redundant wire portion 3Ba. This structure effectively reduces any increase in the connection resistance when the second redundant wire portion 3Bc has the same width and the same thickness as each of the first redundant wire portion 3Bb and third redundant wire portion 3Ba.

The second redundant wire portion 3Bc may be covered with a protective layer. In this case, the second redundant wire portion 3Bc covered with a protective layer can have higher abrasion resistance and higher bond strength to the third connection portion (pad) and the fourth connection portion (pad). The material of the protective layer may be a resin such as an acrylic resin or a polycarbonate resin, or an inorganic compound such as silicon oxide (SiO₂) or silicon nitride (Si₃N₄). The protective layer may contain black conductive components such as carbon particles. Such a protective layer increases the conductivity of the second redundant wire portion 3Bc and allows the narrow frame portion between the edges of the first surface 10a and the image display unit 20 to be less noticeable. The protective layer covering a second redundant wire portion 3Bc may have no contact with the protective layer covering another second redundant wire portion 3Bc adjacent to the second redundant wire portion 3Bc. The protective layers being conductive can reduce short circuiting between the second redundant wire portions 3Bc adjacent to each other. The protective layers covering the adjacent second redundant wire portions 3Bc being nonconductive can be placed in contact or continuous with each other.

As illustrated in FIG. 16, the first redundant wire portions 3Bb, which are connected to the drive 30 at the center of the second surface 10b of the substrate 10, may be longer than the third redundant wire portions 3Ba. When the first redundant wire portions 3Bb and the third redundant wire portions 3Ba are made of the same material, the first redundant wire portions 3Bb may be wider and/or thicker than the third redundant wire portions 3Ba. This structure reduces the resistance of the first redundant wire portions 3Bb and thus reduces the resistance of the drive signal lines 3B.

The multiple redundant drive signal lines 3B may include redundant drive signal lines 3B with lower resistance than the drive signal lines 3. For example, when a redundant drive signal line 3B has a longer path from the drive 30 to the corresponding switch 7 than the drive signal lines 3, the width of the redundant drive signal line 3B may be increased to be greater than the width of the drive signal lines 3. This can reduce the electrical resistance of the redundant drive signal line 3B. The image signal transmitted from the drive 30 to the corresponding switch 7 by the redundant drive signal line 3B is thus less likely to have a voltage drop. When the drive signal lines 3 and the redundant drive signal lines 3B have the same thickness, the redundant drive signal lines 3B may have a width more than once and about five times or less the width of the drive signal lines 3, but the width is not limited to this range. For example, each redundant drive signal line 3B may include any of the first redundant wire portion 3Bb, the second redundant wire portion 3Bc, and the third redundant wire portion 3Ba to be wider than other redundant wire portions. For example, the electrical resistance of the redundant drive signal line 3B may be reduced by increasing the sizes of the third connection portion and the fourth connection portion in the redundant drive signal line 3B to be larger than the size of the first connection portion and the second connection portion in each drive signal line 3.

The multiple redundant drive signal lines 3B may include redundant drive signal lines 3B with a lower specific resistance (resistivity) than the drive signal lines 3. For example, the drive signal lines 3 may be made of soft copper (100.0% in % IACS) or aluminum (59.5% in % IACS), and the redundant drive signal lines 3B may be made of silver (105.7% in % IACS). The drive signal lines 3 may be made of aluminum, and the redundant drive signal lines 3B may be made of soft copper. The drive signal lines 3 may be made of molybdenum (31.4% in % IACS), and the redundant drive signal lines 3B may be made of aluminum.

The structure in each of the examples in FIGS. 16, 17, and 19 includes z redundant drive signal lines 3B (z is a natural number greater than or equal to 2). In other words, the display device 100 includes a first redundant drive signal line 3B1, . . . , and a z-th redundant drive signal line 3Bz.

For example, for every two or more switches 7 among the multiple switches 7, one drive signal line 3 is connected to each of the two or more switches 7 as a normal drive signal line 3. For every two or more switches 7, a branched line of one redundant drive signal line 3B is connected to each of the two or more switches 7. In other words, the multiple switches 7 include, for example, for every two or more drive signal lines 3, at least two switches 7 each connected to the corresponding one of the two or more drive signal lines 3 and connected to a branched line of one of the multiple redundant drive signal lines 3B. Each switch 7 is thus connected to, for example, one drive signal line 3 and one redundant drive signal line 3B. For every two or more switches 7 among the multiple switches 7, for example, one redundant drive signal line 3B is connected to the two or more switches 7. More specifically, the third redundant wire portion 3Ba of one redundant drive signal line 3B includes, for example, at least two portions (also referred to as branch portions) B1 connected to at least two switches 7.

As illustrated in, for example, FIGS. 16, 17, and 19, each of the multiple drive signal lines 3 may extend from the second surface 10b over the first side surface 10c1 to the first surface 10a. Each of the multiple redundant drive signal lines 3B may extend from the second surface 10b over the first side surface 10c1 to the first surface 10a. In this example, for every two or more drive signal lines 3, one redundant drive signal line 3B may be located adjacent to the two or more drive signal lines 3 on the first side surface 10c1. In other words, for example, for every two or more drive signal lines 3 among the drive signal lines 3, a group of signal lines (also referred to as a signal line group) extends on the first side surface 10c1. The signal line group includes the two or more drive signal lines 3 and one redundant drive signal line 3B arranged side by side. The redundant drive signal line 3B is located as a standby line for the two or more drive signal lines 3. The signal line groups are, for example, located in areas spaced from one another in a plan view of the first side surface 10c1. In other words, the multiple signal line groups have, for example, no overlap in a plan view of the first side surface 10c1.

This can reduce, for example, the difference in path length between the wires for transmitting image signals from the drive 30 to the pixel units 2 through the drive signal lines 3 and the wires for transmitting image signals from the drive 30 to the pixel units 2 through the redundant drive signal lines 3B. A voltage drop is thus less likely to occur with image signals provided from, for example, the drive 30 to the pixel units 2 through the redundant drive signal lines 3B instead of through the drive signal lines 3. The display device 100 can thus have less image quality degradation resulting from a broken drive signal line 3 outside the image display unit 20. In one example, for every two or more drive signal lines 3 among the multiple drive signal lines 3, one redundant drive signal line 3B may be located between the two or more drive signal lines 3 on the first side surface 10c1 to produce the same effects.

The two or more drive signal lines 3 are, for example, a predetermined number v of drive signal lines 3 (v is a natural number greater than or equal to two). The predetermined number v is, for example, 2 to the y-th power minus 1 (y is a natural number greater than or equal to 2). In this case, for example, for every (2y−1) switches 7 among the multiple switches 7, one drive signal line 3 is connected to each of the (2y−1) switches 7 as a normal drive signal line. For every (2y−1) switches 7, a branched line of one of the multiple redundant drive signal lines 3B is connected to each of the (2y−1) switches 7. In other words, the multiple switches 7 include, for example, for every (2y−1) drive signal lines 3 among the multiple drive signal lines 3, (2y−1) switches 7 each connected to the corresponding one of the (2y−1) drive signal lines 3 and connected to a branched line of one of the multiple redundant drive signal lines 3B.

In the example below, y is 8, and the predetermined number v is 255. In this example, for every 255 switches 7 among the multiple switches 7, one drive signal line 3 is connected to each of the 255 switches 7 as a normal drive signal line. For every 255 switches 7, a branched line of one of the multiple redundant drive signal lines 3B is connected to each of the 255 switches 7. In other words, the multiple switches 7 include, for example, for every 255 switches 7, 255 switches 7 each connected to the corresponding one of the 255 drive signal lines 3 and connected to a branch line of one of the multiple redundant drive signal lines 3B.

The display device 100 according to the fourth embodiment may include, for example, one redundant drive signal line 3B for every two or more drive signal lines 3 including different numbers of drive signal lines 3.

### 2-5. Sixth Embodiment

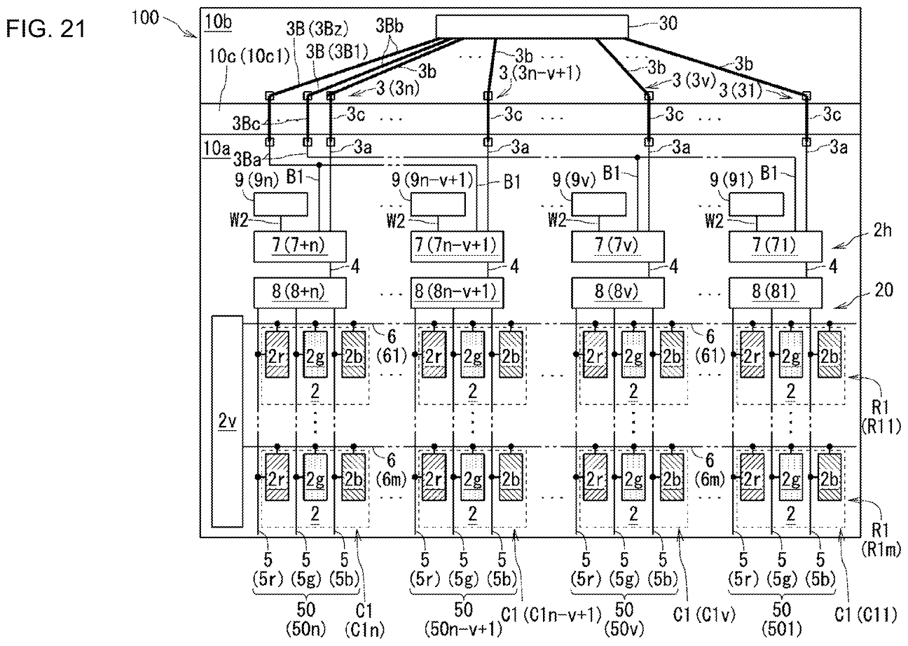

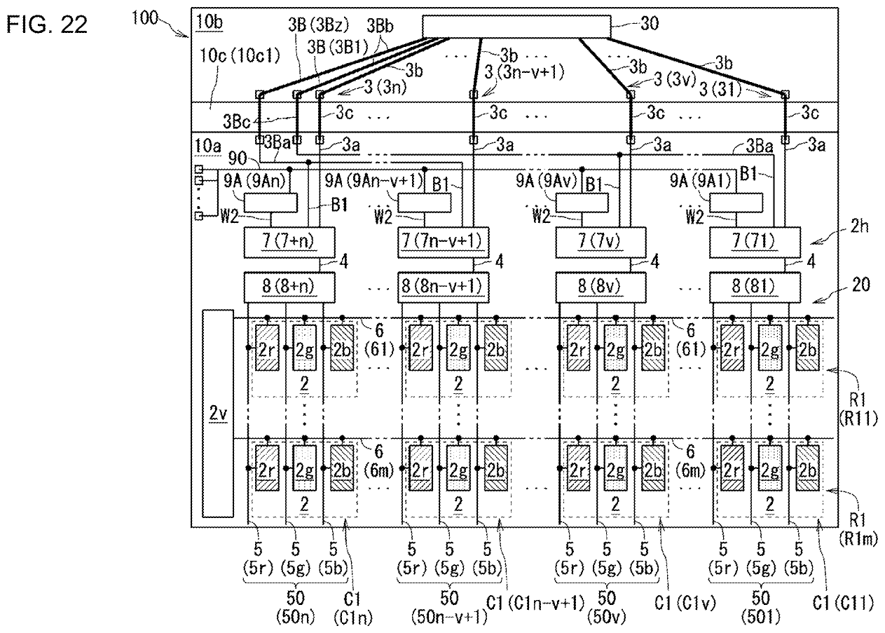

In the fifth embodiment, as illustrated in, for example, FIGS. 21 and 22, each of the multiple redundant drive signal lines 3B extends from the second surface 10b over the first side surface 10c1 to the first surface 10a. Each of the multiple redundant drive signal lines 3B may be separate from the multiple drive signal lines 3 without being located between the multiple drive signal lines 3 on the first side surface 10c1. In other words, when the first side surface 10c1 is viewed in plan in a transparent manner, the first side surface 10c1 may include an area in which the multiple drive signal lines 3 are located and an area in which the multiple redundant drive signal lines 3B are located. The areas are separate from each other. This facilitates the arrangement of the multiple drive signal lines 3 on, for example, the second surface 10b and the first side surface 10c1 of the substrate 10 with, for example, a predetermined pitch.

FIG. 21 is a schematic block diagram of a display device 100 with a first example structure according to a sixth embodiment. The display device 100 illustrated in FIG. 21 includes the structure that is a variation of, for example, the first example structure of the display device 100 according to the fifth embodiment illustrated in FIG. 16, with the multiple redundant drive signal lines 3B being separate from the multiple drive signal lines 3 without being located between the multiple drive signal lines 3 on the second surface 10b and the first side surface 10c1.

FIG. 22 is a schematic block diagram of a display device 100 with a second example structure according to the sixth embodiment. The display device 100 illustrated in FIG. 22 includes the structure that is a variation of, for example, the second example structure of the display device 100 according to the fifth embodiment illustrated in FIG. 19, with the multiple redundant drive signal lines 3B being separate from the multiple drive signal lines 3 without being located between the multiple drive signal lines 3 on the second surface 10b and the first side surface 10c1.

### 2-6. Seventh Embodiment

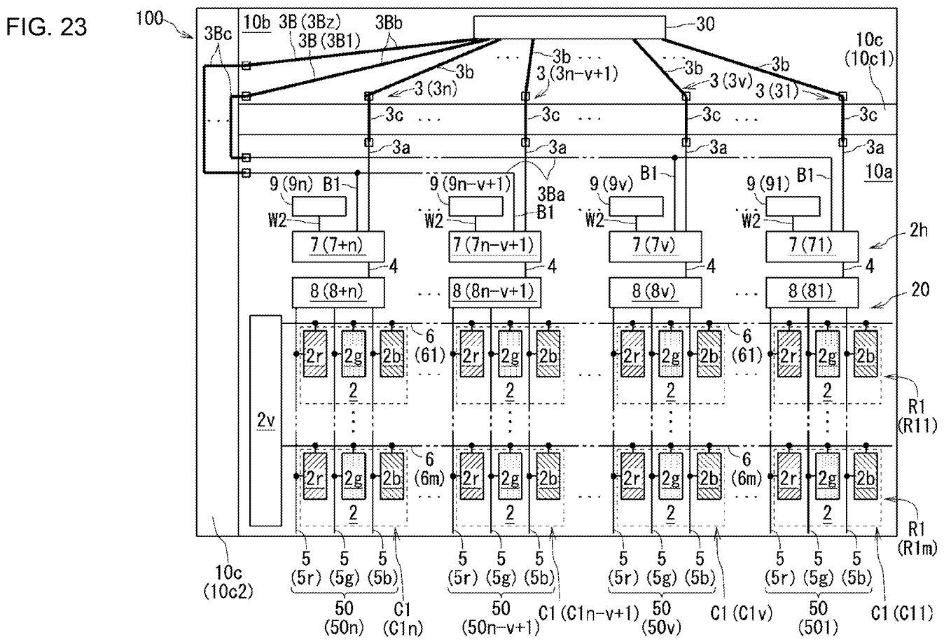

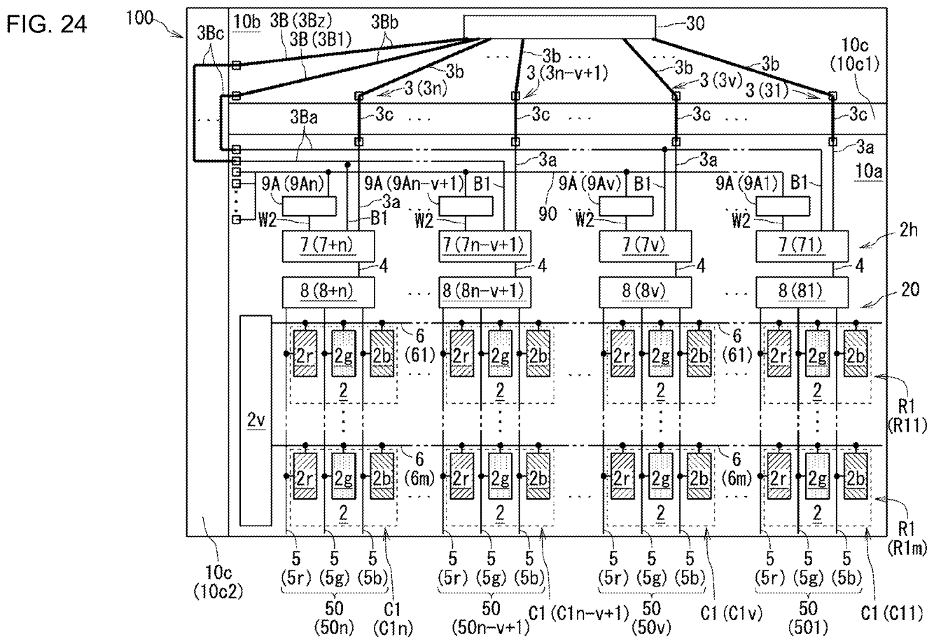

In the sixth embodiment, as illustrated in, for example, FIGS. 23 and 24, each of the multiple drive signal lines 3 may extend from the second surface 10b over the first side surface 10c1 to the first surface 10a. One or more of the multiple redundant drive signal lines 3B may extend from the second surface 10b to the first surface 10a over a side surface 10c of the multiple side surface 10c different from the first side surface 10c1. In other words, at least one of the multiple redundant drive signal lines 3B may extend from the second surface 10b to the first surface 10a over a side surface 10c different from the first side surface 10c1 on which the multiple drive signal lines 3 are located. When one side surface 10c of the substrate 10 receiving the multiple drive signal lines 3B lacks space for the multiple redundant drive signal lines 3B, the structure allows, for example, one or more redundant drive signal line 3B to extend on another side surface 10c of the substrate 10 to facilitate the arrangement of the multiple redundant drive signal lines 3B. In this example, all the multiple redundant drive signal lines 3B may extend from the second surface 10b to the first surface 10a over a side surface 10c different from the first side surface 10c1 on which the multiple drive signal lines 3 extend.

FIG. 23 is a schematic block diagram of a display device 100 with a first example structure according to a seventh embodiment. The display device 100 illustrated in FIG. 23 includes the structure that is a variation of, for example, the first example structure of the display device 100 according to the sixth embodiment illustrated in FIG. 21, with the multiple redundant drive signal lines 3B extending on paths different from the paths extending from the second surface 10b to the first surface 10a over the second side surface 10c2 as a side surface 10c that is different from the first side surface 10c1.

FIG. 24 is a schematic block diagram of a display device 100 with a second example structure according to the seventh embodiment. The display device 100 illustrated in FIG. 24 includes the structure that is a variation of, for example, the second example structure of the display device 100 according to the sixth embodiment illustrated in FIG. 22, with the multiple redundant drive signal lines 3B extending on paths different from the paths extending from the second surface 10b to the first surface 10a over the second side surface 10c2 as a side surface 10c that is different from the first side surface 10c1.

In this example, at least one of the multiple redundant drive signal lines 3B may extend over a side surface 10c different from the first side surface 10c1 or the second side surface 10c2. For example, at least one of the multiple redundant drive signal lines 3B may extend over a side surface 10c different from the side surface 10c over which at least one other redundant drive signal line 3B extends. For example, at least one of the multiple redundant drive signal lines 3B may extend from the second surface 10b over the second side surface 10c2 to the first surface 10a, whereas at least one other multiple redundant drive signal line 3B may extend from the second surface 10b over the fourth side surface 10c4 to the first surface 10a.

### 2-7. Eighth Embodiment

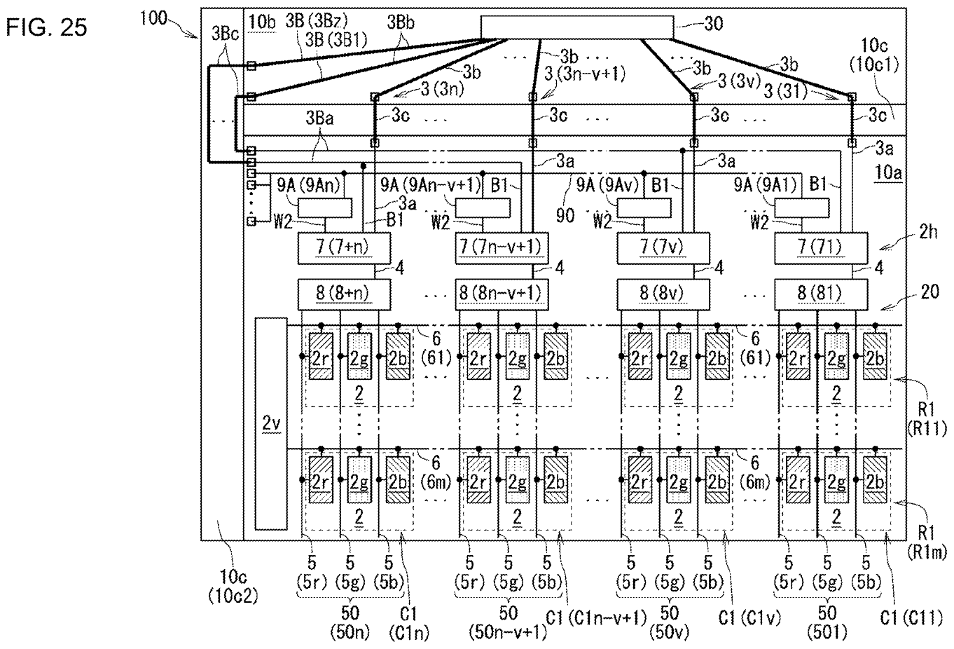

In each of the fifth to seventh embodiments, as illustrated in, for example, FIG. 25, each of the multiple redundant drive signal lines 3B may include two or more wire portions (also referred to as redundant wire portions) 3Bp extending from the drive 30 to the image display unit 20. In other words, each redundant drive signal line 3B may extend from the third redundant wire portion 3Ba including a branch portion B1 connected to the corresponding switch 7 in the image display unit 20 to the drive 30 through each of the two or more redundant wire portions 3Bp. In this example, each redundant drive signal line 3B normally allows image signals to be provided from the drive 30 to the corresponding switch 7 using one of the two or more redundant wire portions 3Bp. When the redundant wire portion 3Bp being used breaks, the other of the two or more redundant wire portions 3Bp can be used to allow image signals to be provided from the drive 30 to the switch 7. When, for example, at least one of the two or more redundant wire portions 3Bp of the redundant drive signal lines 3B breaks due to various factors such as thermal or mechanical distortion, another redundant wire portion 3Bp may be used to continue providing image signals from the redundant drive signal line 3B to the emission control signal lines 5. This can reduce image quality degradation resulting from a broken drive signal line 3 outside the image display unit 20. In this example, at least one of the multiple redundant drive signal lines 3B may include two or more redundant wire portions 3Bp extending from the drive 30 to the image display unit 20. In this example, each of at least two of the multiple redundant drive signal lines 3B may include two or more redundant wire portions 3Bp extending from the drive 30 to the image display unit 20.

FIG. 25 is a schematic block diagram of a display device 100 with an example structure according to an eighth embodiment. The display device 100 illustrated in FIG. 25 includes the structure that is a variation of, for example, the first example structure of the display device 100 according to the fifth embodiment illustrated in FIG. 16, with each of the multiple redundant drive signal lines 3B including two redundant wire portions 3Bp extending from the drive 30 to the image display unit 20.

In the example in FIG. 25, in each of the multiple redundant drive signal lines 3B, the two redundant wire portions 3Bp include a first redundant wire portion 3Bp1 and a second redundant wire portion 3Bp2. Each of the first redundant wire portion 3Bp1 and the second redundant wire portion 3Bp2 includes, for example, the first redundant wire portion 3Bb on the second surface 10b and the second redundant wire portion 3Bc on the side surface 10c. The second redundant wire portion 3Bc of the first redundant wire portion 3Bp1 and the second redundant wire portion 3Bc of the second redundant wire portion 3Bp2 are connected to a third redundant wire portion 3Ba. The third redundant wire portion 3Ba is connected to the corresponding switch 7 at the branch portion B1.

When, for example, the first redundant wire portion 3Bp1 of the two redundant wire portions 3Bp of the redundant drive signal line 3B breaks due to various factors such as thermal or mechanical distortion, the second redundant wire portion 3Bp2 may be used to continue providing image signals from the redundant drive signal line 3B to the emission control signal lines 5. When, for example, the second redundant wire portion 3Bp2 of the two redundant wire portions 3Bp of the redundant drive signal line 3B breaks due to various factors such as thermal or mechanical distortion, the first redundant wire portion 3Bp1 may be used to continue providing image signals from the redundant drive signal line 3B to the emission control signal lines 5. This can reduce image quality degradation resulting from a broken drive signal line 3 outside the image display unit 20.

### 2-8. Ninth Embodiment

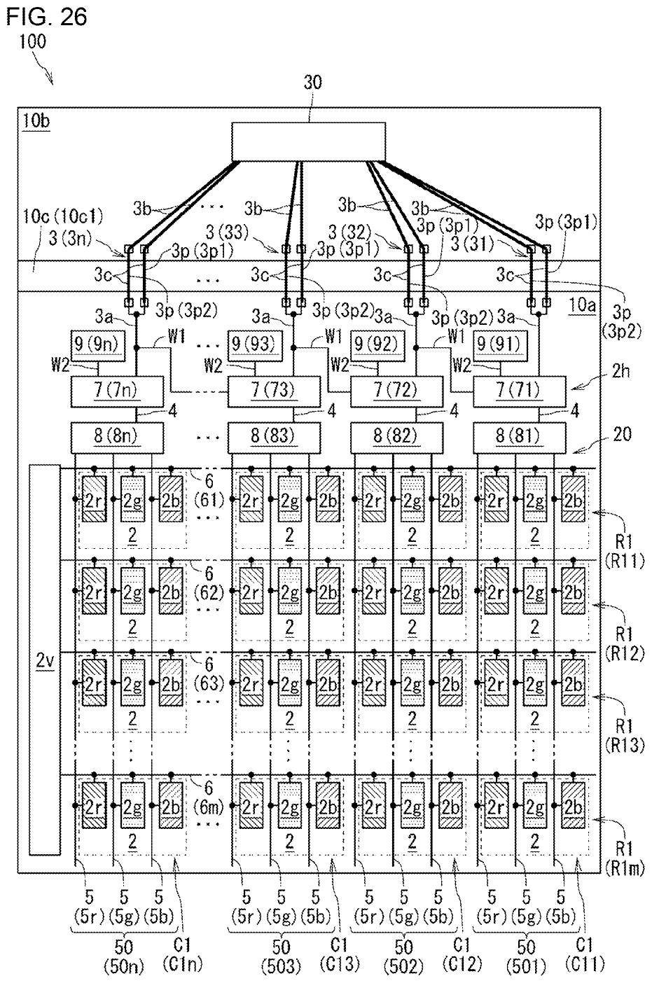

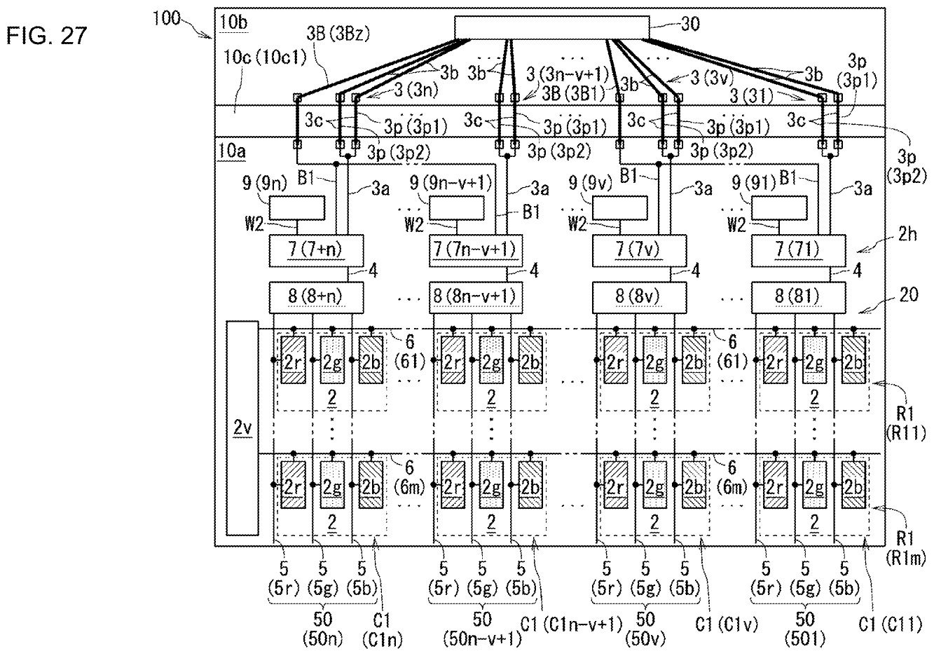

In each of the above embodiments, as illustrated in, for example, FIGS. 26 and 27, each of the multiple drive signal lines 3 may include two or more wire portions 3p extending from the drive 30 to the image display unit 20. In this example, each drive signal line 3 may extend from the third wire portion 3a connected to the corresponding switch 7 or 7B in the image display unit 20 to the drive 30 through each of the two or more wire portions 3p. In this case, each of the multiple drive signal lines 3 normally allows image signals to be provided from the drive 30 to the corresponding switch 7 or 7B using one of the two or more wire portions 3p. When the wire portion 3p being used breaks, the other of the two or more wire portions 3p can be used to allow image signal to be provided from the drive 30 to the switch 7 or 7B. When, for example, at least one wire portion 3p of the two or more wire portions 3p breaks due to various factors such as thermal or mechanical distortion, another wire portion 3p may be used to continue providing image signals from the drive signal line 3 to the emission control signal lines 5. This can reduce image quality degradation resulting from a broken drive signal line 3 outside the image display unit 20. In this example, at least one of the multiple drive signal lines 3 may include two or more wire portions 3p extending from the drive 30 to the image display unit 20. In this example, each of at least two of the multiple drive signal lines 3 may include two or more wire portions 3p extending from the drive 30 to the image display unit 20.

FIG. 26 is a schematic block diagram of a display device 100 with a first example structure according to a ninth embodiment. The display device 100 illustrated in FIG. 26 includes the structure that is a variation of, for example, the structure of the display device 100 according to the first embodiment illustrated in FIG. 5, with each of the multiple drive signal lines 3 including two wire portions 3p extending from the drive 30 to the image display unit 20.

FIG. 27 is a schematic block diagram of a display device 100 with a second example structure according to the ninth embodiment. The display device 100 illustrated in FIG. 27 includes the structure that is a variation of, for example, the first example structure of the display device 100 according to the fifth embodiment illustrated in FIG. 16, with each of the multiple drive signal lines 3 including two wire portions 3p extending from the drive 30 to the image display unit 20.

In the example in each of FIGS. 26 and 27, the two wire portions 3p in each of the multiple drive signal lines 3 include a first wire portion 3p1 and a second wire portion 3p2. Each of the first wire portion 3p1 and the second wire portion 3p2 includes a first wire portion 3b on the second surface 10b and a second wire portion 3c on the side surface 10c. The second wire portion 3c of the first wire portion 3p1 and the second wire portion 3c of the second wire portion 3p2 are connected to a third wire portion 3a. The third wire portion 3a is connected to the corresponding switch 7.

When, for example, the first wire portion 3p1 among the two wire portions 3p in a drive signal line 3 breaks due to various factors such as thermal or mechanical distortion, the second wire portion 3p2 is used to continue providing image signals from the drive signal line 3 to the emission control signal lines 5. When, for example, the second wire portion 3p2 among the two wire portions 3p in the drive signal line 3 breaks due to various factors such as thermal or mechanical distortion, the first wire portion 3p1 may be used to continue providing image signals from the drive signal line 3 to the emission control signal lines 5. This can reduce image quality degradation resulting from a broken drive signal line 3 outside the image display unit 20.

### 3. Others

In each of the above embodiments, each switch 7 or 7B may include, for example, any circuit configuration, other than the circuit configuration described above, to allow selective shifting to the first conductive state or the second conductive state. For example, each switch 7 may include an n-channel transistor and a p-channel transistor that are interchanged at each of the first gate 7G1 and the second gate 7G2. For example, each switch 7B may include an n-channel transistor and a p-channel transistor that are interchanged at each of the first gate 7G1, the second gate 7G2, and the fourth gate 7G4. For example, the first gate 7G1 may be any circuit or element, other than a TG, that is settable to a conductive state to allow image signals to be provided from the normal drive signal line 3 to the emission control signal lines 5 in the emission control signal line group 50 in response to one or more particular signals being input. For example, the second gate 7G2 may be any circuit or element, other than a TG, that is settable to a conductive state to allow image signals to be provided from the additional drive signal line 3 to the emission control signal lines 5 in the emission control signal line group 50 in response to one or more particular signals being input. The first signal may be a H signal and the second signal may be a L signal as appropriate for the circuit configuration of each switch 7 or 7B. In this case, each switch 7 or 7B is, for example, settable to the first conductive state in response to a H signal as the first signal provided from the corresponding switch setter 9 or 9A and to the second conductive state in response to a L signal as the second signal provided from the switch setter 9 or 9A.

In each of the above embodiments, each switch setter 9 or 9A may include, for example, any circuit configurations, other than the specific circuit configuration described above, that can selectively provide either the first signal or the second signal to the corresponding switch 7. For example, each switch setter 9A may include a circuit configuration using one or more other logic gates in place of a NOR gate and may provide the second signal to the corresponding switch 7 or 7B in response to a specific signal such as a specific address corresponding to the switch setter 9A. The first signal may be a H signal and the second signal may be a L signal as appropriate for the circuit configuration of each switch setter 9 or 9A. In this case, each switch 7 or 7B is, for example, settable to the first conductive state in response to a H signal as the first signal provided from the corresponding switch setter 9 or 9A and to the second conductive state in response to a L signal as the second signal provided from the switch setter 9 or 9A.

In each of the above embodiments, when the first surface 10a is, for example, viewed in plan in a transparent manner, a notably narrow portion (narrow frame portion) between the edges of the first surface 10a and the image display unit 20 may be used to place various wires and various circuits. In this case, the scanning signal line driver 2v may be, for example, partly or fully located in the narrow frame portion. The image signal line driver 2h may be partly or fully located in the narrow frame portion. The drive 30 may be, for example, located in the narrow frame portion. In this case, the multiple drive signal lines 3 and the multiple redundant drive signal lines 3B may extend from, for example, the narrow frame portion to the image display unit 20. The narrow frame portion may have a width of 5 to 100 μm, or 10 to 50 μm, but may have a width outside these ranges. In one example, the image display unit 20, the drive 30, and the multiple drive signal lines 3 may be located on a component other than the substrate 10.

In each of the above embodiments, a switch 7 or a switch 7B may be, for example, located for each of selected ones of all the drive signal lines 3 in the display device 100. In other words, a switch 7 or a switch 7B may be, for example, connected to each of the selected ones of all the drive signal lines 3 in the display device 100.

In each of the above embodiments, a switch setter 9 may be, for example, connected to each of selected ones of the multiple switches 7, and a switch setter 9A may be connected to each of the other ones of the multiple switches 7. For example, a switch setter 9 may be, for example, connected to each of the selected ones of the multiple switches 7B, and a switch setter 9A may be connected to each of the other ones of the multiple switches 7B.

In each of the above embodiments, each of the multiple pixel units 2 may include, for example, at least two of the first subpixel 2r, the second subpixel 2g, and the third subpixel 2b. The first subpixel 2r may emit light of the first color that is, for example, other than red. The second subpixel 2g may emit light of the second color that is, for example, other than green. The third subpixel 2b may emit light of the third color that is, for example, other than blue. Each pixel unit 2 may include, for example, the same or similar structure as one subpixel that emits light of one color. In other words, each pixel unit 2 may include a light emitter that emits light of one color, or may include multiple light emitters that emit light of two or more different colors. When, for example, each pixel unit 2 includes a light emitter that emits light of one color, the selectors 8 can be eliminated. In this case, each switch 7 may be, for example, directly connected to the corresponding emission control signal lines 5.

In each of the above embodiments, each of the first surface 10a and the second surface 10b of the substrate 10 may be, for example, different from a rectangular surface with four sides. Each of the first surface 10a and the second surface 10b may be, for example, a polygonal surface, such as a pentagonal surface or a hexagonal surface.

In each of the above embodiments, the display device 100 may be, for example, used as an independent display device without being assembled into the tiled display 900.

The components described in the above embodiments and variations may be entirely or partially combined as appropriate unless any contradiction arises.

### REFERENCE SIGNS

10 substrate
100 display device
10a first surface
10b second surface
10c side surface
10cl to 10c4 first to fourth side surfaces
2 pixel unit
20 image display unit
2b third subpixel
2g second subpixel
2h image signal line driver
2r first subpixel
2v scanning signal line driver
3 drive signal line (normal drive signal line, additional drive signal line)
30 drive
3B redundant drive signal line
3Bp redundant wire portion
3p wire portion
5 emission control signal line
50 emission control signal line group
6 scanning signal line
7, 7B switch
9, 9A switch setter
90 specific signal line group
900 tiled display
9P specific wire portion
C1 pixel column
E1a to E4a first to fourth sides
E1b to E4b first to fourth sides
L1 specific signal line
R1 pixel row

1. A display device comprising:
an image display unit including a plurality of pixel units and a plurality of emission control signal lines configured to supply image signals to columns of pixel units of the plurality of pixel units;
a plurality of drive signal lines configured to supply image signals to the plurality of emission control signal lines; and
a drive configured to supply an image signal to each of the plurality of drive signal lines,
wherein the image display unit further includes a plurality of switches each connected to a corresponding drive signal line of the plurality of drive signal lines,
one normal drive signal line of the plurality of drive signal lines and at least one additional drive signal line different from the one normal drive signal line are connected to a corresponding emission control signal line of the plurality of emission control signal lines through a corresponding switch of the plurality of switches, and
each of the plurality of switches is selectively settable at least to a first conductive state or a second conductive state, the first conductive state is a state to allow an image signal to be provided from the drive to a corresponding emission control signal line of the plurality of emission control signal lines through the one normal drive signal line of the plurality of drive signal lines, and the second conductive state is a state to allow an image signal to be provided from the drive to the corresponding emission control signal line through the at least one additional drive signal line.

2. The display device according to claim 1, wherein
the at least one additional drive signal line is at least one drive signal line of the plurality of drive signal lines.

3. The display device according to claim 2, wherein
the at least one additional drive signal line is one drive signal line of the plurality of drive signal lines.

4. The display device according to claim 2, wherein
the at least one additional drive signal line includes at least two additional drive signal lines of the plurality of drive signal lines, and
each of the plurality of switches supplies, in the second conductive state, to the corresponding emission control signal line, an image signal with a voltage between voltages of at least two image signals supplied respectively from the drive to the at least two additional drive signal lines.

5. The display device according to claim 3, wherein
the at least one additional drive signal line connected to the corresponding switch of the plurality of switches is a drive signal line of the plurality of drive signal lines located adjacent to the one normal drive signal line connected to the switch.

6. The display device according to claim 3, wherein
the at least one additional drive signal line connected to the corresponding switch of the plurality of switches is a drive signal line other than a drive signal line of the plurality of drive signal lines located adjacent to the one normal drive signal line connected to the switch.

7. The display device according to claim 1, further comprising:
a plurality of redundant drive signal lines each located for every two or more drive signal lines of the plurality of drive signal lines,
wherein the drive is configured to supply an image signal to each of the plurality of redundant drive signal lines,
the plurality of switches includes, for every two or more drive signal lines, at least two switches each connected to a corresponding drive signal line of the two or more drive signal lines and to a branched portion of one redundant drive signal line of the plurality of redundant drive signal lines, and
the at least one additional drive signal line is the one redundant drive signal line.

8. The display device according to claim 7, further comprising:
a substrate including a first surface, a second surface opposite to the first surface, and a plurality of side surfaces connecting the first surface and the second surface,
wherein the image display unit is located on the first surface of the substrate,
the drive is located on the second surface of the substrate,
the plurality of side surfaces includes a first side surface connecting a first side of the first surface and a first side of the second surface,
each of the plurality of drive signal lines extends from the second surface to the first surface over the first side surface,
each of the plurality of redundant drive signal lines extends from the second surface to the first surface over the first side surface, and
the one redundant drive signal line is located for every two or more drive signal lines between or adjacent to the two or more drive signal lines on the first side surface.

9. The display device according to claim 7, further comprising:
a substrate including a first surface, a second surface opposite to the first surface, and a plurality of side surfaces connecting the first surface and the second surface,
wherein the image display unit is located on the first surface of the substrate,
the drive is located on the second surface of the substrate,
the plurality of side surfaces includes a first side surface connecting a first side of the first surface and a first side of the second surface,
each of the plurality of drive signal lines extends from the second surface to the first surface over the first side surface, and
each of the plurality of redundant drive signal lines extends from the second surface to the first surface over the first side surface, and is separate from the plurality of drive signal lines without being located between the plurality of drive signal lines on the first side surface.

10. The display device according to claim 7, further comprising:
a substrate including a first surface, a second surface opposite to the first surface, and a plurality of side surfaces connecting the first surface and the second surface,
wherein the image display unit is located on the first surface of the substrate,
the drive is located on the second surface of the substrate,
the plurality of side surfaces includes a first side surface connecting a first side of the first surface and a first side of the second surface,
each of the plurality of drive signal lines extends from the second surface to the first surface over the first side surface, and
at least one of the plurality of redundant drive signal lines extends from the second surface to the first surface over a side surface of the plurality of side surfaces different from the first side surface.

11. The display device according to claim 7, wherein
at least one of the plurality of redundant drive signal lines includes at least two wire portions extending from the drive to the image display unit.

12. The display device according to claim 7, wherein
the plurality of redundant drive signal lines includes a redundant drive signal line having lower resistance than the plurality of drive signal lines.

13. The display device according to claim 8, wherein
each of the plurality of redundant drive signal lines includes a first redundant wire portion on the second surface, a second redundant wire portion on a side surface of the plurality of side surfaces, and a third redundant wire portion on the first surface; and
the second redundant wire portion is wider and/or thicker than each of the first redundant wire portion and the third redundant wire portion.

14. The display device according to claim 1, wherein
at least one of the plurality of drive signal lines includes at least two wire portions extending from the drive to the image display unit.

15. The display device according to claim 8, wherein
each of the plurality of drive signal lines includes a first wire portion on the second surface, a second wire portion on a side surface of the plurality of side surfaces, and a third wire portion on the first surface; and
the second wire portion is wider and/or thicker than each of the first wire portion and the third wire portion.

16. The display device according to claim 1, wherein
the image display unit includes a plurality of switch setters each connected to a corresponding switch of the plurality of switches,
each of the plurality of switch setters selectively provides one of a first signal or a second signal to the corresponding switch connected to the switch setter, and
each of the plurality of switches is settable to the first conductive state in response to the first signal provided from a switch setter of the plurality of switch setters connected to the switch and to the second conductive state in response to the second signal provided from the switch setter.

17. The display device according to claim 16, wherein
each of the plurality of switch setters includes a specific wire portion, and provides the second signal to the corresponding switch connected to the switch setter in response to cutting of the specific wire portion.

18. The display device according to claim 16, wherein
each of the plurality of switch setters provides the second signal to the corresponding switch connected to the switch setter in response to a specific signal corresponding to the switch setter provided from a plurality of specific signal lines.
